(19) United States
(12) Patent Application Publication
(10) Pub. No.: US 2026/0206428 A1
(43) Pub. Date: Jul. 16, 2026

(54) DISPLAY DEVICE, METHOD OF MANUFACTURING THE SAME AND ELECTRONIC DEVICE INCLUDING THE SAME

(71) Applicant: Samsung Display Co., Ltd., Yongin-si (KR)

(72) Inventor: Chungi YOU, Yongin-si (KR)

(73) Assignee: Samsung Display Co., Ltd., Yongin-si (KR)

(21) Appl. No.: 19/410,207

(22) Filed: Dec. 5, 2025

(30) Foreign Application Priority Data
Jan. 13, 2025 (KR) 10-2025-0004827

(51) Int. Cl. H10K 59/123; H10K 59/12; H10K 59/124; H10K 59/131

(52) U.S. Cl. CPC H10K 59/123; H10K 59/1201; H10K 59/124; H10K 59/131

(57) ABSTRACT

A display device includes a base substrate, a first insulating layer defining a gate hole that exposes an upper surface of the base substrate; a first gate electrode filling the gate hole and having a thickness equal to that of the first insulating layer, an active pattern overlapping the first gate electrode in a plan view, a planarization layer defining a contact hole which exposes a portion of the active pattern, a connecting pattern filling the contact hole on the active pattern and contacting the exposed portion of the active pattern, a wiring structure including a semiconductor-element-connecting pattern electrically connected to the connecting pattern and a plurality of wiring layers sequentially stacked, and a light-emitting element electrically connected to the active pattern through the wiring structure and emitting light.

### CROSS-REFERENCE TO RELATED APPLICATION(S)

This application claims priority under 35 U.S.C. §119 to Korean Patent Application No. 10-2025-0004827, filed on January 13, 2025, which is hereby incorporated by reference for all purposes as if fully set forth herein.

### BACKGROUND

### 1. Field

Embodiments relate to a display device, a method of manufacturing the same, and an electronic device including the same. More particularly, embodiments relate to the display device for implementing a high resolution, the method of manufacturing the same, and the electronic device including the same.

### 2. Description of Related Art

A display device may be a device that displays an image for providing visual information to a user. Recently, a method for manufacturing the display device such as OLEDoS (organic light-emitting diode on silicon) for high-resolution implementation may have been under research. First, semiconductor elements may be independently formed on a substrate such as a silicon wafer through a front end of line (FEOL) process. After the FEOL process is completed, the back end of line (BEOL) process may be performed to connect the semiconductor elements and lines, and to connect light-emitting elements with the lines and semiconductor elements, thereby completing the manufacturing of the display device.

However, when a well is formed in the silicon wafer due to a doping process for forming a channel, a source, and a drain of the semiconductor element during the FEOL process, a problem occurs in that the manufacturing cost of the display device increases. Accordingly, research is underway for methods to reduce manufacturing cost, such as by implementing high resolution while reducing the number of times equipment (e.g., photo masks, deposition equipment, and the like) is used.

### SUMMARY

Embodiments provide a display device with reduced manufacturing cost.

Embodiments provide a method of manufacturing the display device.

Embodiments provide an electronic device including the display device.

A display device according to an embodiment includes a base substrate, a first insulating layer arranged on the base substrate and defining a gate hole which exposes an upper surface of the base substrate, a first gate electrode arranged on the base substrate, filling the gate hole, and having a thickness equal to a thickness of the first insulating layer, an active pattern arranged on the first gate electrode and overlapping the first gate electrode in a plan view, a planarization layer arranged on the active pattern and defining a contact hole that exposes a portion of the active pattern, a connecting pattern filling the contact hole on the active pattern and contacting the portion of the active pattern which is exposed, a wiring structure arranged on the planarization layer and including a semiconductor-element-connecting pattern electrically connected to the connecting pattern, and a plurality of wiring layers sequentially stacked, and a light-emitting element electrically connected to the active pattern through the wiring structure and configured to emit light.

In an embodiment, the display device may further include a first gate insulating layer arranged between the first gate electrode and the active pattern in a cross-sectional view and a second insulating layer arranged on the first gate insulating layer and covering the active pattern.

In an embodiment, a thickness of the active pattern may be equal to a thickness of the first gate insulating layer.

In an embodiment, the connecting pattern may penetrate the second insulating layer and the planarization layer in a thickness direction.

In an embodiment, the display device may further include a second gate insulating layer arranged on the active pattern and a second gate electrode arranged on the second gate insulating layer and overlapping the active pattern in a plan view.

In an embodiment, the first gate electrode, the second gate electrode, the active pattern, and the connecting pattern define a transistor, the first gate electrode is a lower gate electrode of the transistor, and the second gate electrode is an upper gate electrode of the transistor.

In an embodiment, the base substrate may include a silicon wafer.

In an embodiment, the first insulating layer may include silicon oxycarbide (SiOC).

A method of manufacturing the display device according to an embodiment includes forming a first insulating layer having a gate hole on a base substrate, forming a first gate electrode on the base substrate, filling the gate hole and having a thickness equal to a thickness of the first insulating layer, forming an active pattern on the first insulating layer of which a portion overlaps the first gate electrode in a plan view, forming a connecting pattern on the active pattern, the connecting pattern contacting a portion of the active pattern, forming a wiring structure including an insulating structure and a plurality of wiring layers sequentially stacked in the insulating structure, and electrically connecting the connecting pattern to the wiring structure.

In an embodiment, the forming of the first gate electrode may include forming a gate hole exposing an upper surface of the base substrate by removing a portion of the first insulating layer in a thickness direction, applying a metal material filling the gate hole, and performing a planarization process in which an upper surface of the metal material and an upper surface of the first insulating layer have an equal level based on the base substrate.

In an embodiment, the forming of the active pattern may include forming a first gate insulating layer on the first gate electrode and the first insulating layer, forming a preliminary active layer covering the first gate insulating layer entirely on the first gate insulating layer, performing a first doping process on the preliminary active layer to form a channel, and forming a preliminary active pattern by patterning the preliminary active layer which is doped.

In an embodiment, the forming of the active pattern further may include forming a second insulating layer on the preliminary active pattern, forming a mask pattern on the second insulating layer, the mask pattern overlapping a portion of the preliminary active pattern and the first gate electrode in a plan view, and performing a second doping process on the preliminary active pattern to form a source and a drain.

In an embodiment, the forming of the active pattern further may include forming a second gate insulating layer on the preliminary active pattern, forming a second gate electrode on the second gate insulating layer, the second gate electrode overlapping a portion of the preliminary active pattern and the first gate electrode in a plan view, and performing a second doping process on the preliminary active pattern using the second gate electrode as a mask to form a source and a drain.

In an embodiment, the forming of the connecting pattern may include forming a planarization layer on the active pattern, form a contact hole which exposes a portion of the active pattern by removing a portion of the planarization layer in a thickness direction, and filling the contact hole with the connecting pattern.

In an embodiment, the first gate electrode, the active pattern, and the connecting pattern define a transistor, the base substrate, the first insulating layer, and the transistor are included in a semiconductor element layer, and the semiconductor element layer is formed through a FEOL process.

In an embodiment, the forming of the wiring structure is performed through a BEOL process.

In an embodiment, the wiring structure may include a semiconductor-element-connecting pattern located at a lower portion of the wiring structure and a light-emitting element connecting pattern located at an upper portion of the wiring structure, and in the connecting of the connecting pattern and the wiring structure, the connecting pattern contacts the semiconductor-element-connecting pattern.

In an embodiment, the method may further include forming a light-emitting element layer including a pixel electrode, a light-emitting layer, and a common electrode sequentially stacked on the wiring structure, the light-emitting layer configured to emit light, and connecting the wiring structure and the light-emitting element layer, and in the connecting of the wiring structure and the light-emitting element layer, the light-emitting element connecting pattern contacts the pixel electrode.

An electronic device according to an embodiment includes a processor configured to output an image data signal and an input control signal and a display device configured to driven based on the image data signal and the input control signal, and the display device includes a base substrate, a first insulating layer arranged on the base substrate and defining a gate hole which exposes an upper surface of the base substrate, a first gate electrode arranged on the base substrate, filling the gate hole, and having a thickness equal to a thickness of the first insulating layer, an active pattern arranged on the first gate electrode and overlapping the first gate electrode in a plan view, a planarization layer arranged on the active pattern and defining a contact hole that exposes a portion of the active pattern, a connecting pattern filling the contact hole on the active pattern and contacting the portion of the active pattern which is exposed, a wiring structure arranged on the planarization layer and including a semiconductor-element-connecting pattern electrically connected to the connecting pattern, and a plurality of wiring layers sequentially stacked, and a light-emitting element electrically connected to the active pattern through the wiring structure and configured to emit light.

In an embodiment, the base substrate, the first insulating layer, the first gate electrode, the active pattern, the planarization layer, and the connecting pattern may be formed through a FEOL process, and the wiring structure may be formed through a BEOL process.

In a display device according to embodiments of the present disclosure, since structures for a high-resolution implementation may be easily formed on a silicon wafer substrate through a FEOL process and a BEOL process, the display device with improved display quality may be provided.

In a method of manufacturing the display device according to embodiments of the present disclosure, since an active pattern is formed on the upper portion of a gate electrode, rather than forming a doped well in a process of forming a semiconductor element layer through the FEOL process, manufacturing cost and time of the semiconductor element layer may be reduced compared to a case in which the well is formed.

In an electronic device according to embodiments of the present disclosure, the electronic device may include the display device and a processor configured to input an image data signal and/or an input control signal to the display device. Accordingly, since the electronic device includes the display device manufactured according to the manufacturing method, the manufacturing cost and time of the electronic device may be reduced.

### BRIEF DESCRIPTION OF DRAWINGS

Illustrative, non-limiting embodiments will be more clearly understood from the following detailed description in conjunction with the accompanying drawings.

FIG. 1 is a plan view illustrating a display device according to an embodiment of the present disclosure.

FIG. 2 is a circuit diagram illustrating one pixel included in the display device of FIG. 1.

FIG. 3 is a cross-sectional view illustrating an example of a portion of a cross section of the display device of FIG. 1.

FIGS. 4, 5, 6, 7, 8, 9, 10, 11, 12, 13, 14, 15, and 16 are views illustrating a method for manufacturing the display device of FIG. 3.

FIG. 17 is a view illustrating a conventional display device for explaining the effect of the display device of FIG. 1.

FIG. 18 is a cross-sectional view illustrating another example of a portion of a cross section of the display device of FIG. 1.

FIGS. 19, 20, 21, 22, 23, and 24 are views illustrating a method for manufacturing the display device of FIG. 18.

FIG. 25 is a block diagram of an electronic device according to an embodiment.

FIG. 26 is schematic views of electronic devices according to various embodiments.

### DETAILED DESCRIPTION OF EMBODIMENTS

The embodiments of the present disclosure disclosed herein are provided to illustrate specific structural or functional descriptions for the purpose of describing the embodiments of the present disclosure only. The embodiments of the present disclosure may be implemented in various forms and should not be construed as being limited to the embodiments described herein.

The present disclosure may be modified in various ways and may take various forms. Specific embodiments are illustrated in the drawings and will be described in detail in the specification. However, this is not intended to limit the present disclosure to the particular forms disclosed, and it is to be understood that all modifications, equivalents, and substitutions that fall within the spirit and scope of the present disclosure are included.

Terms such as first and second may be used to describe various elements, but the elements should not be limited by these terms. These terms are used to distinguish one element from another. For example, a first element may be referred to as a second element without departing from the scope of the present disclosure, and similarly, the second element may also be referred to as the first element.

When it is mentioned that one component is "connected to" or "coupled to" another component, it should be understood that the component may be directly connected or coupled to the other component, or another component may be interposed therebetween. In contrast, when it is mentioned that one component is "directly connected to" or "directly coupled to" another component, it should be understood that there is no other component interposed therebetween. Other expressions describing relationships between components, such as "between" and "directly between," or "adjacent to" and "directly adjacent to," should be interpreted in the same manner.

The terms used in this application are intended merely to describe specific embodiments and are not intended to limit the present disclosure. Unless clearly indicated otherwise in the context, singular expressions include plural expressions. As used herein, the terms "include" or "have" are intended to indicate the presence of stated features, numbers, steps, operations, components, parts, or combinations thereof, but are not intended to preclude the possibility that one or more other features, numbers, steps, operations, components, parts, or combinations thereof may be present or added.

Unless otherwise defined, all terms used herein, including technical and scientific terms, have the same meanings as commonly understood by one of ordinary skill in the art to which the present disclosure pertains. Terms such as those defined in commonly used dictionaries should be interpreted as having meanings consistent with their usage in the context of the relevant technical field and are not to be interpreted in an idealized or overly formal sense unless expressly defined herein.

Meanwhile, when certain embodiments can be implemented differently, the functions or operations specified in a particular block may occur in a different order from that specified in a flowchart. For example, two consecutive blocks may actually be performed substantially simultaneously, or the blocks may be performed in reverse order, depending on the related functions or operations.

Hereinafter, embodiments of the present disclosure will be described in more detail with reference to the accompanying drawings. In the drawings, like reference numerals are used for like elements, and repeated descriptions of the same elements will be omitted.

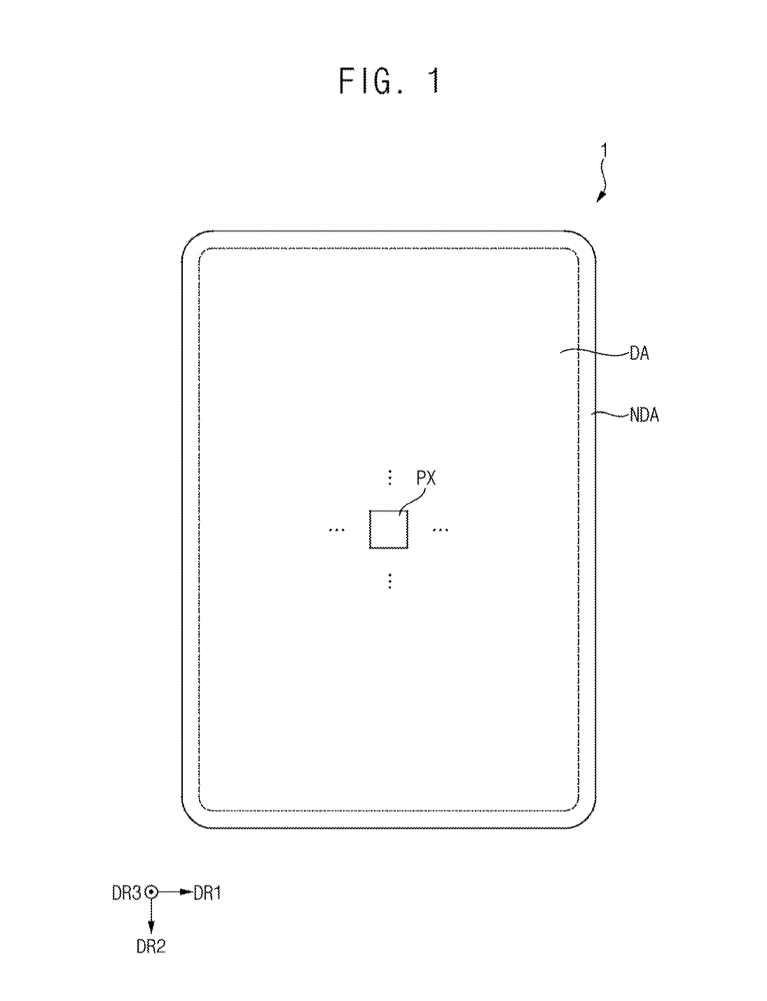

FIG. 1 is a plan view illustrating a display device according to an embodiment of the present disclosure.

Referring to FIG. 1, the display device 1 may include a display area DA and a non-display area NDA. The display area DA may be defined as an area capable of displaying an image by generating light or adjusting the transmittance of light provided from an external light source. The non-display area NDA may be defined as an area that does not generate light and does not display an image. However, the non-display area NDA according to the embodiments of the present disclosure may not be limited thereto, and a configuration that emits light (e.g., a pixel PX) may also be arranged in the non-display area NDA.

At least one pixel PX that emits light may be arranged in the display area DA. A plurality of pixels PX may be arranged in the display area DA. For example, the pixels PX may be arranged in the display area DA in a first direction DR1 and a second direction DR2 to form a matrix. The pixels PX may include sub-pixels that emit light of different colors. For example, the sub-pixels may include first, second, and third sub-pixels, where the first sub-pixel emits light of a first color, the second sub-pixel emits light of a second color, and the third sub-pixel emits light of a third color. In an embodiment, the first color may be red, the second color may be green, and the third color may be blue. However, colors of light emitted by each of the sub-pixels included in the pixels PX according to the embodiments of the present disclosure may not be limited thereto and may include various colors such as magenta, cyan, yellow, and the like.

The non-display area NDA may surround at least a portion of the display area DA. For example, the non-display area NDA may entirely surround the display area DA in a plan view. A driver for driving the pixels PX may be arranged in the non-display area NDA. The driver may provide a signal and/or voltage to the pixels PX. For example, the driver may include a data driver, a scan driver, a light-emitting driver, a power voltage generator, a timing controller, and the like.

In an embodiment, the display device 1 may include lines extending from the driver toward the pixels PX. For example, the lines may include data lines extending from the data driver toward the pixels PX to deliver a data voltage to the pixels PX, scan lines extending from the scan driver toward the pixels PX to deliver a scan signal to the pixels PX, and light-emitting lines extending from the light-emitting driver toward the pixels PX to deliver a light-emitting signal to the pixels PX. However, types of the lines according to the embodiments of the present disclosure may not be limited thereto.

In an embodiment, the display device 1 may include at least one of an organic light-emitting diode (OLED) including an organic light-emitting layer, a quantum dot light-emitting diode (QLED) including a quantum dot light-emitting layer, an inorganic light-emitting diode including an inorganic semiconductor, a micro light-emitting diode (micro-LED), and a micro organic light-emitting diode (micro-OLED).

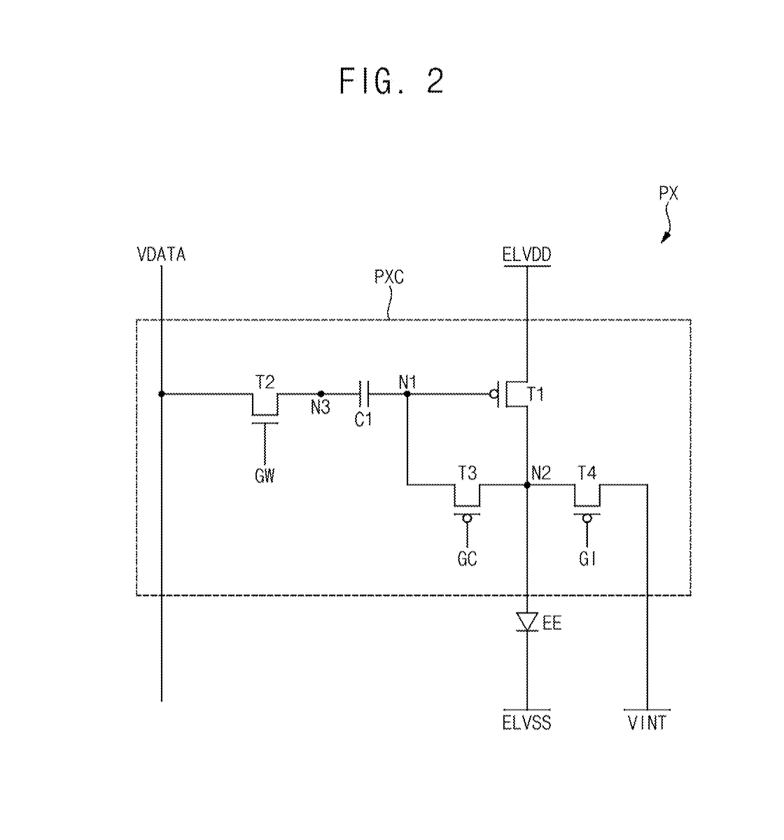

FIG. 2 is a circuit diagram illustrating one pixel included in the display device of FIG. 1.

Referring to FIG. 2, one pixel PX among a plurality of pixels may include a pixel circuit portion PXC and a light-emitting element EE. The pixel circuit portion PXC may include a first transistor T1, a second transistor T2, a third transistor T3, a fourth transistor T4, and a first capacitor C1. The pixel circuit portion PXC may provide a driving current to the light-emitting element EE, and the light-emitting element EE may generate light based on the driving current. The light-emitting element EE may be supplied with a first power voltage ELVSS.

The first transistor T1 may include a gate electrode connected to a first node N1, a first electrode to which a second power voltage ELVDD is applied, and a second electrode connected to a second node N2. The first transistor T1 may generate the driving current based on a voltage between the first node N1 and the second node N2, that is, the voltage stored in the first capacitor C1. The first transistor T1 may be referred to as a driving transistor for generating the driving current. The first transistor T1 may provide the driving current to the light-emitting element EE.

The second transistor T2 may include a gate electrode to which a gate write signal GW is applied, a first electrode connected to a data voltage line, and a second electrode connected to a third node N3. Accordingly, the second transistor T2 may be turned on or off by the gate write signal GW. For example, the second transistor T2 may apply a data voltage VDATA, provided from the data voltage line, to the third node N3 in response to the gate write signal GW. The second transistor T2 may be referred to as a write transistor or a scan transistor for transmitting the data voltage VDATA.

The third transistor T3 may include a gate electrode to which a gate compensation signal GC is applied, a first electrode connected to the first node N1, and a second electrode connected to the second node N2. Accordingly, the third transistor T3 may be turned on or off by the gate compensation signal GC. For example, the third transistor T3 may diode-connect the first node N1 and the second node N2 in response to the gate compensation signal GC. Accordingly, the threshold voltage of the first transistor T1 may be compensated through the diode connecting structure of the third transistor T3. Specifically, during a period in which the third transistor T3 is turned on by the gate compensation signal GC having an active level, the threshold voltage of the first transistor T1 is compensated, so that the pixel PX may emit light with a target luminance accurately. The third transistor T3 may be referred to as a compensation transistor for compensating the threshold voltage of the first transistor T1.

The fourth transistor T4 may include a gate electrode to which a gate initialization signal GI is applied, a first electrode to which an initialization voltage VINT is applied, and a second electrode connected to the second node N2. Accordingly, the fourth transistor T4 may be turned on or off by the gate initialization signal GI. For example, the fourth transistor T4 may apply the initialization voltage VINT to the second node N2 in response to the gate initialization signal GI. The fourth transistor T4 may be referred to as an initialization transistor for initializing the second node N2.

The first capacitor C1 may include a first electrode connected to the first node N1 and a second electrode connected to the third node N3. The first capacitor C1 may store the data voltage VDATA delivered through the second transistor T2. The first capacitor C1 may be referred to as a storage capacitor for storing the data voltage VDATA.

The light-emitting element EE may include a first terminal (e.g., an anode terminal) and a second terminal (e.g., a cathode terminal). The first terminal of the light-emitting element EE may be connected to the second node N2, and the second terminal may be supplied with the second power voltage ELVSS. The light-emitting element EE may generate light with luminance corresponding to the driving current.

In an embodiment, the first power voltage ELVSS may have a voltage level different from that of the second power voltage ELVDD. For example, the voltage level of the first power voltage ELVSS may be lower than the voltage level of the second power voltage ELVDD. However, the relationship between the voltage levels of the first power voltage ELVSS and the second power voltage ELVDD according to the embodiments of the disclosure may not be limited thereto.

In an embodiment, each of the first, second, third, and fourth transistors T1, T2, T3, and T4 may be a PMOS. However, the types of the first, second, third, and fourth transistors T1, T2, T3, and T4 according to the embodiments of the disclosure may not be limited thereto, and at least one transistor among the first, second, third, and fourth transistors T1, T2, T3, and T4 may be an NMOS.

In an embodiment, at least one transistor among the first, second, third, and fourth transistors T1, T2, T3, and T4 may have a lower gate structure or an upper gate structure. In an embodiment, at least one transistor among the first, second, third, and fourth transistors T1, T2, T3, and T4 may have a dual gate structure including a lower gate electrode and an upper gate electrode.

In FIG. 2, the number of transistors included in one pixel PX among the plurality of pixels is illustrated as four, and the number of capacitors is illustrated as one. However, the number of transistors and capacitors included in one pixel according to the embodiments of the disclosure may not be limited thereto. For example, one pixel may include three or fewer or five or more transistors, or may include two or more capacitors.

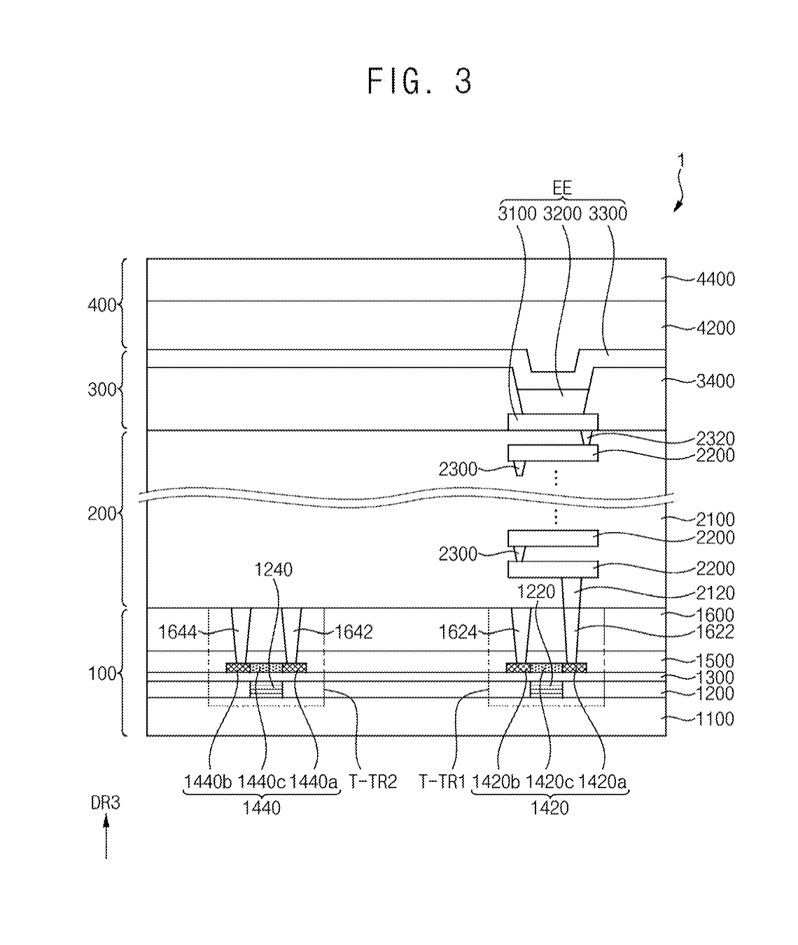

FIG. 3 is a cross-sectional view illustrating an example of a portion of a cross section of the display device of FIG. 1.

Referring to FIG. 3, the display device 1 may include a semiconductor element layer 100, a wiring structure 200, a light-emitting element layer 300, and an upper functional layer 400. The semiconductor element layer 100 may include a base substrate 1100, a first insulating layer 1200, a first gate electrode 1220, a second gate electrode 1240, a gate insulating layer 1300, a first active pattern 1420, a second active pattern 1440, a second insulating layer 1500, a planarization layer 1600, a first connecting pattern 1622, a second connecting pattern 1624, a third connecting pattern 1642, and a fourth connecting pattern 1644.

In the disclosure, the first gate electrode 1220 and the second gate electrode 1240 may be referred to collectively as a first gate electrode. In addition, the gate insulating layer 1300 may be referred to as a first gate insulating layer.

The wiring structure 200 may include an insulating structure 2100, a semiconductor-element-connecting pattern 2120, a plurality of wiring layers 2200, a plurality of wiring contact patterns 2300, and a pixel-electrode-connecting pattern 2320. The light-emitting element layer 300 may include a pixel electrode 3100, a light-emitting layer 3200, a common electrode 3300, and a pixel defining layer 3400. The upper functional layer 400 may include an encapsulation layer 4200 and an optical functional layer 4400.

The first gate electrode 1220, the first active pattern 1420, the first connecting pattern 1622, and the second connecting pattern 1624 may together define a first-type transistor T-TR1. The second gate electrode 1240, the second active pattern 1440, the third connecting pattern 1642, and the fourth connecting pattern 1644 may together define a second-type transistor T-TR2. The pixel electrode 3100, the light-emitting layer 3200, and the common electrode 3300 may together define a light-emitting element EE.

The base substrate 1100 may form the base of the semiconductor element layer 100. In an embodiment, the base substrate 1100 may include a semiconductor material, for example, a group IV semiconductor, a III-V compound semiconductor, or a II-VI compound semiconductor. These may be used alone or in combination. For example, the base substrate 1100 may be a silicon wafer substrate. Specifically, to implement high resolution, the base substrate 1100 may be a silicon wafer substrate, and the display device 1, which is an organic light-emitting display device using the base substrate 1100, may be referred to as an OLEDoS (OLED on silicon) display device. The OLEDoS display device may implement ultra-high definition exceeding 8K on a relatively small area of about 1 inch to about 2 inch and may allow for dense control of pixels (e.g., the pixel PX of FIG. 1) arranged with ultra-high resolution on the semiconductor substrate base substrate 1100. However, numerical values used to describe the OLEDoS display device according to embodiments of the disclosure may not be limited thereto.

In addition a type of the base substrate 1100 or the material included in the base substrate 1100 according to embodiments of the disclosure may not be limited thereto. For example, the base substrate 1100 may include glass, quartz, plastic, and the like. Specifically, the base substrate 1100 may include polymer resins such as polyethersulphone, polyacrylate, polyetherimide, polyethylene naphthalate, polyethylene terephthalate, polyphenylene sulfide, polyarylate, polyimide, polycarbonate, cellulose acetate propionate, and the like. These may be used alone or in combination. For example, the base substrate 1100 may have a multilayer structure including a barrier layer comprising an inorganic insulating material between two or more layers comprising the above polymer resins.

The first insulating layer 1200 may be arranged on the base substrate 1100. In an embodiment, the first insulating layer 1200 may include an inorganic insulating material. For example, the inorganic insulating material may include silicon oxide (SiOₓ), silicon nitride (SiNₓ), silicon oxynitride (SiOₓN_{y}), silicon carbide (SiC), or silicon oxycarbide (SiOC). These may be used alone or in combination. In an embodiment, the first insulating layer 1200 may have a substantially flat upper surface.

The first gate electrode 1220 may be arranged on the base substrate 1100 and may serve as a gate electrode of the first-type transistor T-TR1. In an embodiment, the first gate electrode 1220 may be arranged in a same layer as the first insulating layer 1200. In another embodiment, the first gate electrode 1220 may be arranged in the first insulating layer 1200. For example, a first gate hole (e.g., the first gate hole GH1 of FIG. 5) exposing an upper surface of the base substrate 1100 may be defined in the first insulating layer 1200. The first gate electrode 1220 may fill the first gate hole GH1.

In an embodiment, the upper surface of the first gate electrode 1220 may be substantially flat with the upper surface of the first insulating layer 1200. For example, a thickness of the first gate electrode 1220 may be equal to a thickness of the first insulating layer 1200. Specifically, a step may not be formed around the first gate electrode 1220 filling the first gate hole GH1 and the adjacent first insulating layer 1200, and an upper surface of the first gate electrode 1220 may be connected to the upper surface of the first insulating layer 1200.

The second gate electrode 1240 may be arranged on the base substrate 1100 and may serve as a gate electrode of the second-type transistor T-TR2. In an embodiment, the second gate electrode 1240 may be arranged in a same layer as the first insulating layer 1200. In another embodiment, the second gate electrode 1240 may be arranged in the first insulating layer 1200. For example, a second gate hole (e.g., the second gate hole GH2 of FIG. 5) exposing the upper surface of the base substrate 1100 may be defined in the first insulating layer 1200. The second gate electrode 1240 may fill the second gate hole GH2 .

In an embodiment, an upper surface of the second gate electrode 1240 may be substantially flat with an upper surface of the first insulating layer 1200. For example, a thickness of the second gate electrode 1240 may be equal to a thickness of the first insulating layer 1200. Specifically, a step may not be formed around the second gate electrode 1240 filling the second gate hole GH2 and the adjacent first insulating layer 1200, and the upper surface of the second gate electrode 1240 may be connected to the upper surface of the first insulating layer 1200.

In an embodiment, the first gate electrode 1220 and the second gate electrode 1240 may include a conductive material. For example, the conductive material may include copper (Cu), titanium (Ti), aluminum (Al), molybdenum (Mo), and the like. These may be used alone or in combination. In an embodiment, the first gate electrode 1220 and the second gate electrode 1240 may include a same material. For example, the first gate electrode 1220 and the second gate electrode 1240 may be formed through a same process and arranged in a same layer.

The gate insulating layer 1300 may be arranged on the first insulating layer 1200. For example, the gate insulating layer 1300 may cover upper portions of the first insulating layer 1200, the first gate electrode 1220, and the second gate electrode 1240. In an embodiment, the gate insulating layer 1300 may have a substantially flat upper surface. In an embodiment, a thickness (e.g., a length in a third direction DR3) of the gate insulating layer 1300 may be less than a thickness of the first insulating layer 1200. However, thickness relationship between the first insulating layer 1200 and the gate insulating layer 1300 according to the embodiments of the disclosure may not be limited thereto.

In an embodiment, the gate insulating layer 1300 may include an inorganic insulating material. For example, the gate insulating layer 1300 may include silicon oxide (SiOₓ), silicon nitride (SiNₓ), silicon oxynitride (SiOₓN_{y}), silicon carbide (SiC), silicon oxycarbide (SiOC), and the like. These may be used alone or in combination.

The first active pattern 1420 may be arranged on the gate insulating layer 1300. The first active pattern 1420 may include a first drain region 1420a, a first source region 1420b, and a first channel area 1420c. In an embodiment, the first active pattern 1420 may overlap the first gate electrode 1220 in a plan view. Specifically, the first channel area 1420c of the first active pattern 1420 may overlap the first gate electrode 1220 in a plan view. In other words, the first channel area 1420c may be a portion of the first active pattern 1420 that overlaps the first gate electrode 1220.

In an embodiment, the first active pattern 1420 may include a semiconductor material. For example, the first active pattern 1420 may include polycrystalline silicon or low temperature polycrystalline silicon (LTPS). These may be used alone or in combination. However, the first active pattern 1420 according to embodiments of the disclosure may not be limited thereto and may include an oxide semiconductor.

The second active pattern 1440 may be arranged on the gate insulating layer 1300. The second active pattern 1440 may include a second drain region 1440a, a second source region 1440b, and a second channel area 1440c. In an embodiment, the second active pattern 1440 may overlap the second gate electrode 1240 in a plan view. Specifically, the second channel area 1440c of the second active pattern 1440 may overlap the second gate electrode 1240 in a plan view. In other words, the second channel area 1440c may be a portion of the second active pattern 1440 that overlaps the second gate electrode 1240.

In an embodiment, the first channel area 1420c may be doped with a lower concentration of dopants than the first drain region 1420a and the first source region 1420b or may be an area where dopants are not doped. In an embodiment, the second channel area 1440c may be doped with a lower concentration of dopants than the second drain region 1440a and the second source region 1440b or may be an undoped area.

In an embodiment, the second active pattern 1440 may include a semiconductor material. For example, the second active pattern 1440 may include polycrystalline silicon or low temperature polycrystalline silicon (LTPS). These may be used alone or in combination. However, the second active pattern 1440 according to embodiments of the disclosure may not be limited thereto and may include an oxide semiconductor.

In an embodiment, the first active pattern 1420 and the second active pattern 1440 may include the same material. For example, the first active pattern 1420 and the second active pattern 1440 may be formed through the same process. For example, the first active pattern 1420 and the second active pattern 1440 may be arranged on the same layer.

The second insulating layer 1500 may be arranged on the gate insulating layer 1300. For example, the second insulating layer 1500 may cover the first active pattern 1420 and the second active pattern 1440 on the gate insulating layer 1300. In an embodiment, the second insulating layer 1500 may have a single-layer structure. In another embodiment, the second insulating layer 1500 may have a multilayer structure in which a plurality of layers are stacked. In an embodiment, the second insulating layer 1500 may have a substantially flat upper surface.

In an embodiment, the second insulating layer 1500 may include an inorganic insulating material and/or an organic insulating material. For example, the second insulating layer 1500 may include silicon oxide (SiOₓ), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zirconium oxide (ZrO₂). These may be used alone or in combination.

The planarization layer 1600 may be arranged on the second insulating layer 1500. In an embodiment, the planarization layer 1600 may have a substantially flat upper surface. In an embodiment, the planarization layer 1600 may include an organic insulating material.

The first connecting pattern 1622 may contact the first drain region 1420a. For example, the first connecting pattern 1622 may penetrate through the second insulating layer 1500 and the planarization layer 1600 in a thickness direction and contact the first drain region 1420a. In an embodiment, the first connecting pattern 1622 may include a conductive material. For example, the first connecting pattern 1622 may include copper (Cu), aluminum (Al), tungsten (W), titanium (Ti), and the like.

The second connecting pattern 1624 may contact the first source region 1420b. For example, the second connecting pattern 1624 may penetrate through the second insulating layer 1500 and the planarization layer 1600 in a thickness direction and contact the first source region 1420b. In an embodiment, the second connecting pattern 1624 may include a conductive material. For example, the second connecting pattern 1624 may include copper (Cu), aluminum (Al), tungsten (W), titanium (Ti), and the like.

The third connecting pattern 1642 may contact the second drain region 1440a. For example, the third connecting pattern 1642 may penetrate through the second insulating layer 1500 and the planarization layer 1600 in a thickness direction and contact the second drain region 1440a. In an embodiment, the third connecting pattern 1642 may include a conductive material. For example, the third connecting pattern 1642 may include copper (Cu), aluminum (Al), tungsten (W), titanium (Ti), and the like.

The fourth connecting pattern 1644 may contact the second source region 1440b. For example, the fourth connecting pattern 1644 may penetrate through the second insulating layer 1500 and the planarization layer 1600 in a thickness direction and contact the second source region 1440b. In an embodiment, the fourth connecting pattern 1644 may include a conductive material. For example, the fourth connecting pattern 1644 may include copper (Cu), aluminum (Al), tungsten (W), titanium (Ti), and the like.

In an embodiment, the first, second, third, and fourth connecting patterns 1622, 1624, 1642, and 1644 may include a same material. For example, the first, second, third, and fourth connecting patterns 1622, 1624, 1642, and 1644 may be formed through a same process. For example, the first, second, third, and fourth connecting patterns may be arranged on the same layer. The first connecting pattern 1622 and the second connecting pattern 1624 may electrically connect the first active pattern 1420 to wiring layers in the wiring structure 200. The third connecting pattern 1642 and the fourth connecting pattern 1644 may electrically connect the second active pattern 1440 to wiring layers in the wiring structure 200.

In an embodiment, the first, second, third, and fourth connecting patterns 1622, 1624, 1642, and 1644 may fill holes penetrating through the second insulating layer 1500 and the planarization layer 1600 in the thickness direction. In an embodiment, the upper surfaces of the first, second, third, and fourth connecting patterns may be substantially flat with the upper surface of the planarization layer 1600. In other words, the upper surfaces of the connecting patterns may be connected to the planarization layer 1600 without forming a step difference.

In an embodiment, the first-type transistor T-TR1 may be a driving transistor included in the pixel, and the second-type transistor T-TR2 may be a switching transistor included in the pixel and electrically connected to the driving transistor. For example, the first-type transistor T-TR1 may be the first transistor T1 in FIG. 2. In addition, the second-type transistor T-TR2 may correspond to one among the second transistor T2, the third transistor T3, or the fourth transistor T4 of FIG. 2.

The insulating structure 2100 may be arranged on the planarization layer 1600. In an embodiment, the insulating structure 2100 may have a multilayer structure in which multiple layers are stacked. In another embodiment, the insulating structure 2100 may have a single-layer structure. In an embodiment, the insulating structure 2100 may have a substantially flat upper surface.

In an embodiment, the insulating structure 2100 may include an organic insulating material and/or an inorganic insulating material. For example, the insulating structure 2100 may include silicon oxide (SiOₓ), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), zirconium oxide (ZrO₂), polyimide (PI), polyethersulfone (PES), polycarbonate (PC), benzocyclobutene (BCB), hexamethyldisiloxane (HMDSO), tetraethyl orthosilicate (TEOS), fluorinated tetraethyl orthosilicate (FTEOS), and the like. These may be used alone or in combination.

The semiconductor-element-connecting pattern 2120 may be arranged on the planarization layer 1600. The semiconductor-element-connecting pattern 2120 may be located in the insulating structure 2100. For example, the semiconductor-element-connecting pattern 2120 may be located at a bottom in the insulating structure 2100 and may contact the first connecting pattern 1622. In an embodiment, the semiconductor-element-connecting pattern 2120 may include a conductive material.

The plurality of wiring layers 2200 may be arranged on the planarization layer 1600. The plurality of wiring layers 2200 may be located in the insulating structure 2100. An one wiring layer among the wiring layers 2200 located at a bottom of the insulating structure 2100 may contact the semiconductor-element-connecting pattern 2120. At least two of the wiring layers 2200 may overlap in a plan view. The wiring layers 2200 may serve functions such as capacitor formation, heat dissipation, and the like. The number and arrangement of the wiring layers 2200 according to embodiments of the disclosure may not be limited to what is illustrated of FIG. 3, and the wiring layers may have various numbers and arrangements in the insulating structure 2100.

The plurality of wiring contact patterns 2300 may electrically connect the wiring layers 2200 to one another. For example, in a cross-sectional view, the wiring contact patterns 2300 may be arranged between adjacent wiring layers that are arranged on different levels.

The pixel-electrode-connecting pattern 2320 may be arranged on the plurality of heat dissipation layers 2200. The pixel-electrode-connecting pattern 2320 may be located in the insulating structure 2100. For example, the pixel-electrode-connecting pattern 2320 may be located at a top in the insulating structure 2100. The pixel-electrode-connecting pattern 2320 may contact the pixel electrode 3100. In an embodiment, the pixel-electrode-connecting pattern 2320 may include a conductive material.

In an embodiment, the semiconductor element layer 100 may be formed through a FEOL process. In an embodiment, the wiring structure 200 may be formed through a BEOL process. In an embodiment, after the semiconductor element layer 100 and the wiring structure 200 are formed, the semiconductor element layer 100 and the wiring structure 200 may be electrically connected to each other. For example, the first connecting pattern 1622 of the semiconductor element layer 100 and the semiconductor-element-connecting pattern 2120 of the wiring structure 200 may be connected and/or bonded to each other.

The pixel electrode 3100 may be arranged on the wiring structure 200. The pixel electrode 3100 may be the first terminal of the light-emitting element EE (e.g., an anode terminal). The pixel electrode 3100 may be electrically connected to the pixel-electrode-connecting pattern 2320 of the wiring structure 200.

In an embodiment, the pixel electrode 3100 may include metal, alloy, conductive metal oxide, conductive metal nitride, or transparent conductive material. For example, the pixel electrode 3100 may include silver (Ag) and indium tin oxide (ITO). These may be used alone or in combination. In an embodiment, the pixel electrode 3100 may have a single-layer structure. In another embodiment, the pixel electrode 3100 may have a multilayer structure.

The light-emitting layer 3200 may be arranged on the pixel electrode 3100. In an embodiment, the light-emitting layer 3200 may be entirely arranged on the pixel electrode 3100 and the pixel defining layer 3400. However, the light-emitting layer 3200 according to embodiments of the disclosure may not be limited thereto, and the light-emitting layer 3200 may also be arranged in the hole of the pixel defining layer 3400. In an embodiment, the light-emitting layer 3200 may include an organic light-emitting material. The organic light-emitting material may include a low molecular organic compound or a high molecular organic compound. However, the disclosure may not be limited thereto, and the light-emitting layer 3200 may also include a material such as quantum dots.

The common electrode 3300 may be arranged on the pixel defining layer 3400. In an embodiment, the common electrode 3300 may be arranged on the light-emitting layer 3200. In an embodiment, the common electrode 3300 may include metal, alloy, conductive metal oxide, conductive metal nitride, or transparent conductive material. For example, the common electrode 3300 may include aluminum (Al), platinum (Pt), silver (Ag), magnesium (Mg), gold (Au), chromium (Cr), tungsten (W), titanium (Ti), and the like. These may be used alone or in combination.

The pixel defining layer 3400 may be arranged on the wiring structure 200. In an embodiment, the pixel defining layer 3400 may partially cover the pixel electrode 3100. Specifically, a hole exposing a central portion of the pixel electrode 3100 may be defined in the pixel defining layer 3400, and the pixel defining layer 3400 may cover an edge portion of the pixel electrode 3100. In an embodiment, the pixel defining layer 3400 may include an organic insulating material. In an embodiment, the pixel defining layer 3400 may further include a light-blocking material.

In an embodiment, after the semiconductor element layer 100 and the wiring structure 200 are connected to each other, the light-emitting element layer 300 may be formed on the wiring structure 200, so that the light-emitting element EE, the semiconductor element layer 100, and the wiring structure 200 may be electrically connected to each other. For example, the pixel-electrode-connecting pattern 2320 of the wiring structure 200 and the pixel electrode 3100 of the light-emitting element layer 300 may be connected to each other.

The encapsulation layer 4200 may be arranged on the common electrode 3300. In an embodiment, the encapsulation layer 4200 may include at least one organic layer and/or at least one inorganic layer. For example, the encapsulation layer 4200 may have a structure in which a first inorganic layer, an organic layer, and a second inorganic layer are sequentially stacked along a third direction DR3. The encapsulation layer 4200 may cover the light-emitting element EE to prevent moisture or foreign substances from penetrating into the light-emitting element EE.

The optical functional layer 4400 may control the refraction, visibility, or shielding of light emitted from the light-emitting layer 3200. In an embodiment, the optical functional layer 4400 may include a color filter layer overlapping the light-emitting layer 3200 in a plan view and a light-blocking layer overlapping the pixel defining layer 3400 in a plan view. In another embodiment, the optical functional layer 4400 may include a polarizing layer. For example, when the optical functional layer 4400 includes the polarizing layer, the optical functional layer 4400 may be arranged on the polarizing layer and may further include a light control film for adjusting a viewing angle of emitted or incident light.

However, components included in the display device 1 according to embodiments of the disclosure may not be limited thereto, and the display device 1 may further include a support structure or a lower cover structure arranged under the base substrate 1100, or an upper protective structure or an optical structure arranged on the optical functional layer 4400.

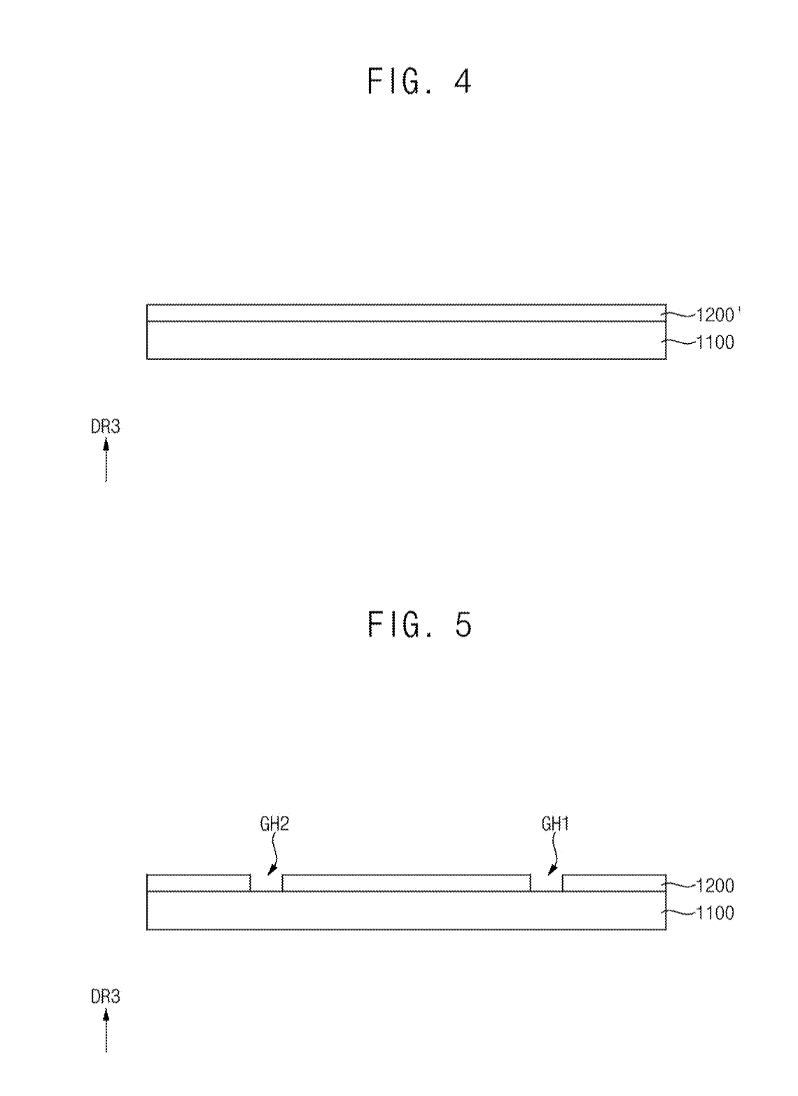

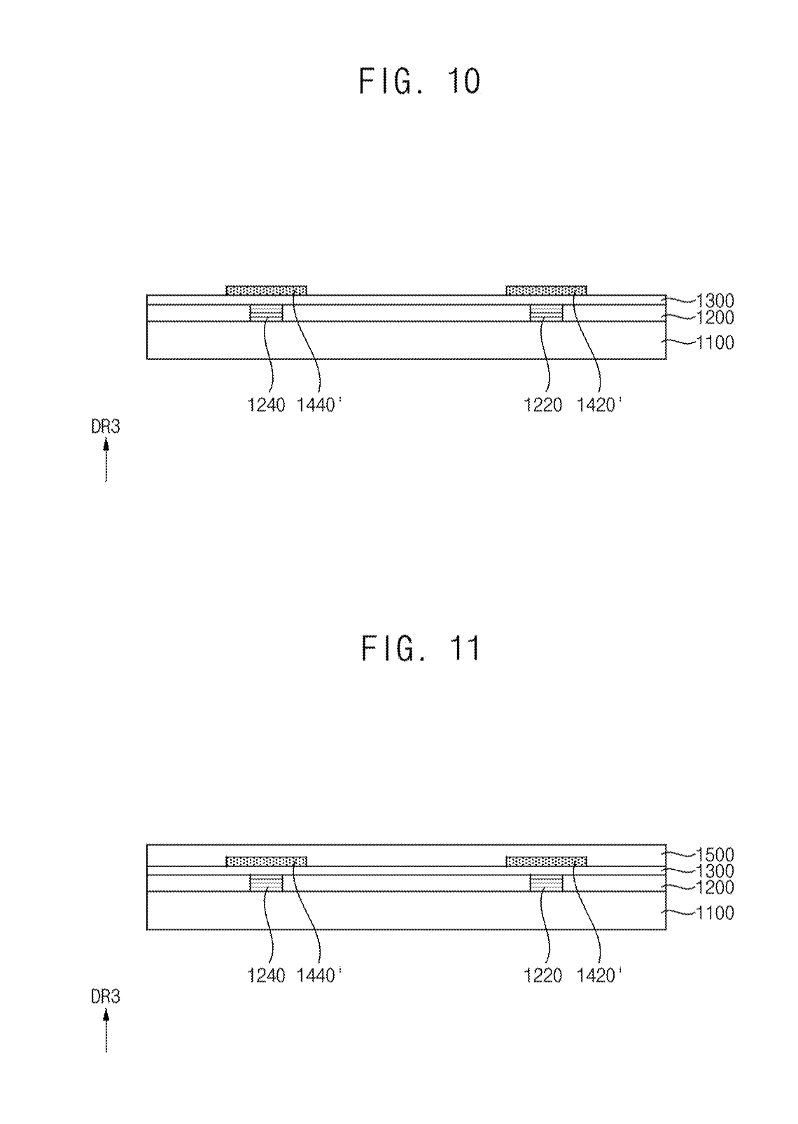

FIGS. 4, 5, 6, 7, 8, 9, 10, 11, 12, 13, 14, 15, and 16 are views illustrating a method for manufacturing the display device of FIG. 3.

Hereinafter, descriptions overlapping with those explained with reference to FIG. 3 may be omitted or briefly described.

Referring to FIGS. 4 and 5, a preliminary insulating layer 1200’ may be formed on the base substrate 1100. In an embodiment, the preliminary insulating layer 1200’ may entirely cover the base substrate 1100. In an embodiment, the preliminary insulating layer 1200’ may have a substantially flat upper surface.

In an embodiment, the preliminary insulating layer 1200’ may include an inorganic insulating material. For example, the inorganic insulating material may include silicon oxide (SiOₓ), silicon nitride (SiNₓ), silicon oxynitride (SiOₓN_{y}), silicon carbide (SiC), or silicon oxycarbide (SiOC). These may be used alone or in combination.

After the preliminary insulating layer 1200’ is formed, a portion of the preliminary insulating layer 1200’ may be removed. For example, the portion of the preliminary insulating layer 1200’ may be removed by etching. In an embodiment, a first gate hole GH1 and a second gate hole GH2 exposing the upper surface of the base substrate 1100 may be formed by removing a portion of the preliminary insulating layer 1200’. Accordingly, the preliminary insulating layer 1200’ may be formed into a first insulating layer 1200 in which the first gate hole GH1 and the second gate hole GH2 are defined.

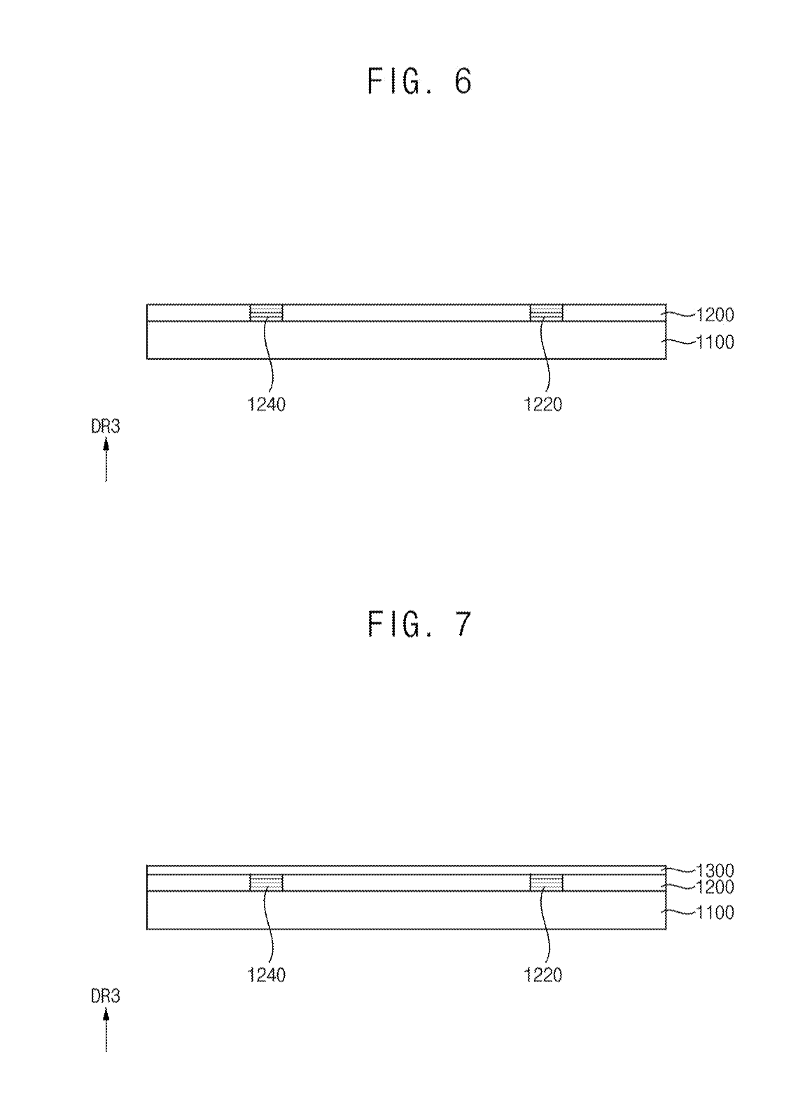

Referring to FIG. 6, a first gate electrode 1220 filling the first gate hole GH1 may be formed on the base substrate 1100. A second gate electrode 1240 filling the second gate hole GH2 may be formed on the base substrate 1100. A conductive material included in the first gate electrode 1220 and the second gate electrode 1240 may be applied toward the first gate hole GH1 and the second gate hole GH2. After the first gate hole GH1 and the second gate hole GH2 are filled with the conductive material, a planarization process may be performed so that the conductive material has a flat upper surface with the first insulating layer 1200. In an embodiment, the planarization process may be chemical mechanical polishing (CMP). For example, through the planarization process, an upper surface of the first gate electrode 1220 and an upper surface of the second gate electrode 1240 may have a same level as an upper surface of the first insulating layer 1200 based on the base substrate 1100. Accordingly, the first gate electrode 1220 and the second gate electrode 1240 may be formed.

Referring to FIG. 7, a gate insulating layer 1300 may be formed on the first insulating layer 1200, the first gate electrode 1220, and the second gate electrode 1240. The gate insulating layer 1300 may include an inorganic insulating material. For example, the inorganic insulating material may include silicon oxide (SiOₓ), silicon nitride (SiNₓ), silicon oxynitride (SiOₓN_{y}), silicon carbide (SiC), or silicon oxycarbide (SiOC). These may be used alone or in combination. In an embodiment, a thickness of the first insulating layer 1200 may be about 100Å to about 400Å. Preferably, the thickness of the first insulating layer 1200 may be about 150Å to about 350Å. However, the thickness range of the first insulating layer 1200 according to embodiments of the present disclosure may not be limited thereto.

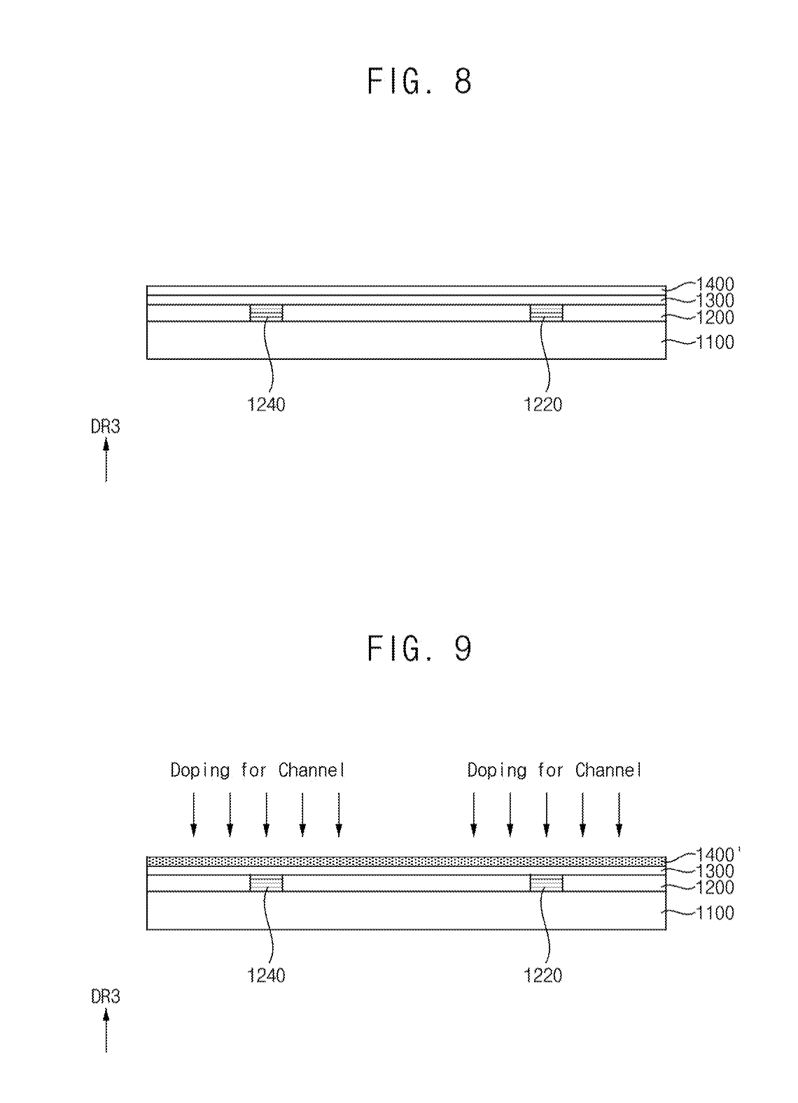

Referring to FIGS. 8, 9, and 10, a preliminary active layer 1400 may be formed on the gate insulating layer 1300. For example, the preliminary active layer 1400 may entirely cover the gate insulating layer 1300. In an embodiment, the preliminary active layer 1400 may include polycrystalline silicon or low temperature polycrystalline silicon (LTPS). These may be used alone or in combination. However, the material included in the preliminary active layer 1400 according to embodiments of the disclosure may not be limited thereto.

In an embodiment, a thickness of the preliminary active layer 1400 may be about 100Å to about 400Å. Preferably, the thickness of the preliminary active layer 1400 may be about 150Å to about 350Å. However, a thickness range of the preliminary active layer 1400 according to embodiments of the present disclosure may not be limited thereto. In an embodiment, the thickness of the preliminary active layer 1400 may be the same as the thickness of the first insulating layer 1200.

In an embodiment, the preliminary active layer 1400 may be polycrystalline silicon or low temperature polycrystalline silicon formed through a crystallization process. For example, an amorphous silicon layer may be formed on the gate insulating layer 1300, and the crystallization process may be performed on the amorphous silicon layer to form the preliminary active layer 1400. The crystallization process may be a laser crystallization process using a laser. However, a crystallization method of the preliminary active layer 1400 according to embodiments of the disclosure may not be limited thereto.

After the preliminary active layer 1400 is formed, a process for forming a channel of a transistor may be performed. For example, the preliminary active layer 1400 may be doped to form a doped preliminary active layer 1400’. In addition, the doped preliminary active layer 1400’ may be patterned to remove a portion of the doped preliminary active layer 1400’. Accordingly, a first preliminary active pattern 1420' and a second preliminary active pattern 1440’ may be formed. However, in the preliminary active layer 1400 according to embodiments of the disclosure, doping may not be performed, and only patterning of the preliminary active layer 1400 may be performed. In the disclosure, doping of the preliminary active layer 1400 for channel formation may be referred to as a first doping process.

Referring to FIG. 11, a second insulating layer 1500 may be formed on the gate insulating layer 1300. For example, the second insulating layer 1500 may be formed on the gate insulating layer 1300 so as to cover the first preliminary active pattern 1420’ and the second preliminary active pattern 1440’.

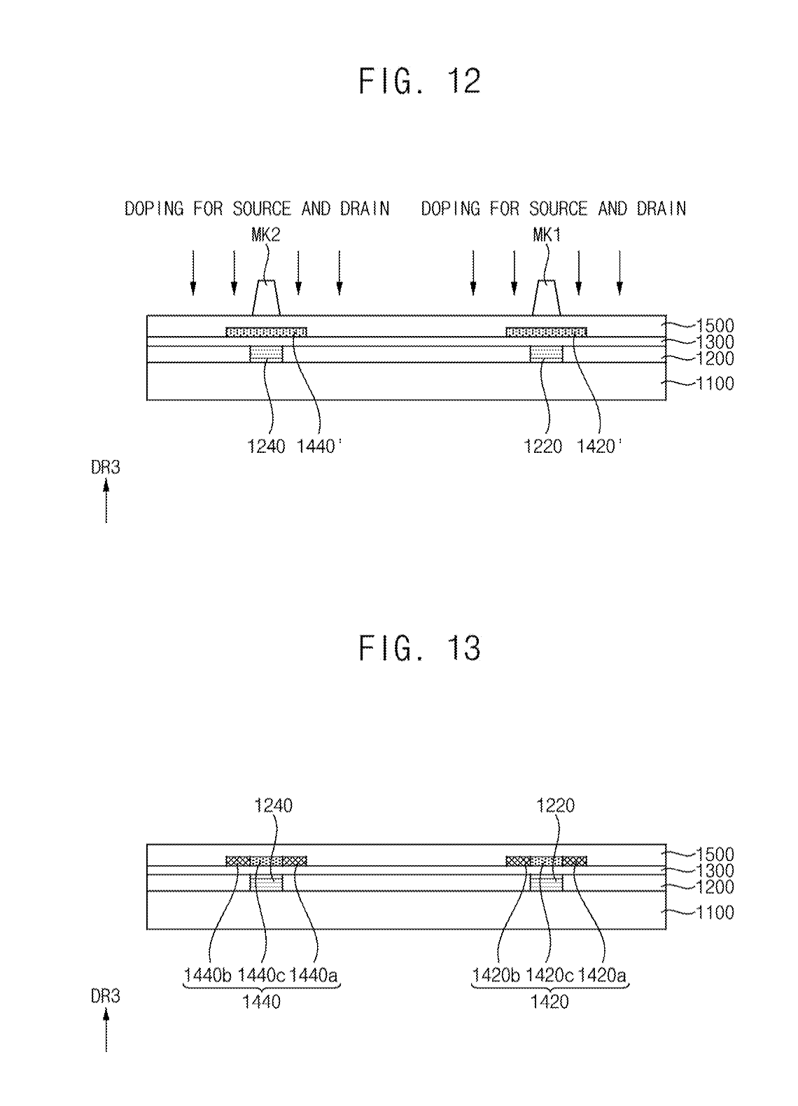

Referring to FIGS. 12 and 13, a first mask pattern MK1 and a second mask pattern MK2 may be formed on the second insulating layer 1500. In an embodiment, each of the first mask pattern MK1 and the second mask pattern MK2 may be a photoresist.

In an embodiment, the first mask pattern MK1 may be formed to overlap the first gate electrode 1220 in a plan view. Specifically, the first mask pattern MK1 may be formed to overlap a portion of the first preliminary active pattern 1420’ that overlaps the first gate electrode 1220 in a plan view.

In an embodiment, the second mask pattern MK2 may be formed to overlap the second gate electrode 1240 in a plan view. Specifically, the second mask pattern MK2 may be formed to overlap a portion of the second preliminary active pattern 1440’ that overlaps the second gate electrode 1240 in a plan view.

After the first mask pattern MK1 is formed, doping may be performed on the first preliminary active pattern 1420’. For example, to form a source and a drain of the transistor, doping may be performed on a portion of the first preliminary active pattern 1420’ that does not overlap the first mask pattern MK1 in a plan view. In other words, the first mask pattern MK1 may serve to mask the first preliminary active pattern 1420’ that overlaps the first mask pattern MK1 in a plan view so as not to be doped. Accordingly, the doped portion of the first preliminary active pattern 1420’ may form a first drain region 1420a and a first source region 1420b. Therefore, a first active pattern 1420 including the first drain region 1420a, the first source region 1420b, and a first channel area 1420c may be formed.

After the second mask pattern MK2 is formed, doping may be performed on the second preliminary active pattern 1440’. For example, to form a source and a drain of the transistor, doping may be performed on a portion of the second preliminary active pattern 1440’ that does not overlap the second mask pattern MK2 in a plan view. In other words, the second mask pattern MK2 may serve to mask the second preliminary active pattern 1440’ that overlaps the second mask pattern MK2 in a plan view so as not to be doped. Accordingly, the doped portion of the second preliminary active pattern 1440’ may form a second drain region 1440a and a second source region 1440b. Therefore, a second active pattern 1440 including the second drain region 1440a, the second source region 1440b, and a second channel area 1440c may be formed. In the disclosure, the doping of the first and second preliminary active patterns 1420’, 1440’ for forming the source and drain may be referred to as a first doping process.

After the first active pattern 1420 and the second active pattern 1440 are formed, the first mask pattern MK1 and the second mask pattern MK2 may be removed from the second insulating layer 1500.

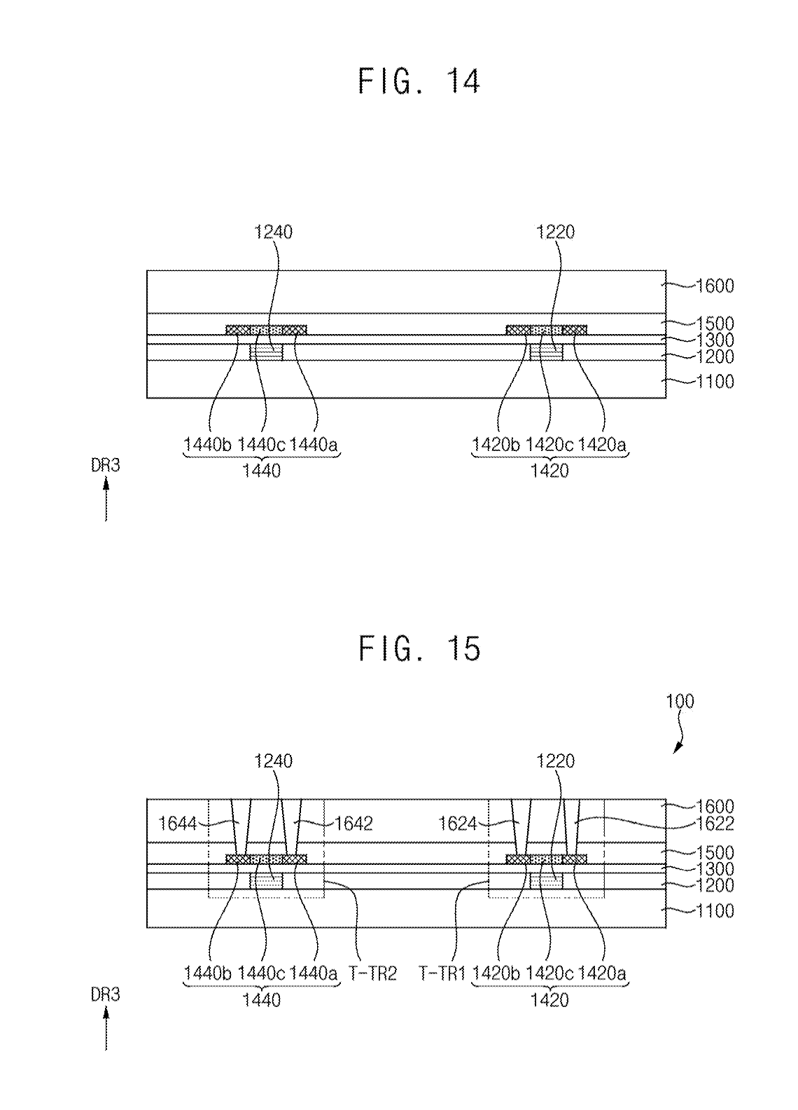

Referring to FIGS. 14 and 15, a planarization layer 1600 may be formed on the second insulating layer 1500. After the planarization layer 1600 is formed, a contact hole penetrating the second insulating layer 1500 and the planarization layer 1600 in a thickness direction may be formed. For example, the contact hole may include a first contact hole exposing an upper surface of the first drain region 1420a, a second contact hole exposing an upper surface of the first source region 1420b, a third contact hole exposing an upper surface of the second drain region 1440a, and a fourth contact hole exposing an upper surface of the second source region 1440b.

After the contact holes are formed, a first connecting pattern 1622, a second connecting pattern 1624, a third connecting pattern 1642, and a fourth connecting pattern 1644 filling the respective contact holes may be formed. For example, the first connecting pattern 1622 may fill the first contact hole and may contact the first drain region 1420a. In addition, the second connecting pattern 1624 may fill the second contact hole and may contact the first source region 1420b. In addition, the third connecting pattern 1642 may fill the third contact hole and may contact the second drain region 1440a. In addition, the fourth connecting pattern 1644 may fill the fourth contact hole and may contact the second source region 1440b. Accordingly, a semiconductor element layer 100 may be formed.

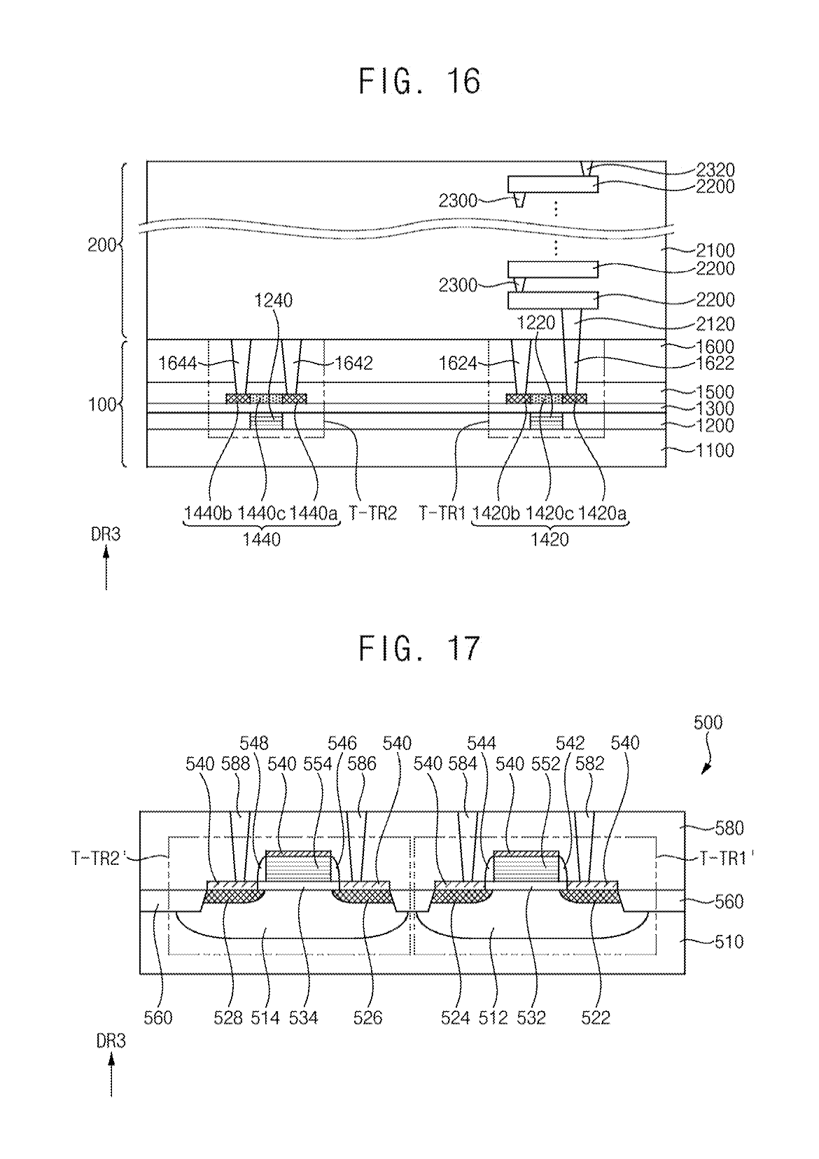

Referring to FIG. 16, the wiring structure 200 including the insulating structure 2100, the semiconductor-element-connecting pattern 2120, the plurality of wiring layers 2200, the plurality of wiring contact patterns 2300, and the pixel-electrode-connecting pattern 2320 may be formed. After the wiring structure 200 is formed, the semiconductor element layer 100 and the wiring structure 200 may be connected to each other. Specifically, referring further to FIG. 3, the first connecting pattern 1622 of the semiconductor element layer 100 and the semiconductor device contact pattern 2120 of the wiring structure 200 may contact each other.

After the semiconductor element layer 100 and the wiring structure 200 are connected to each other, the light-emitting element layer 300 and an upper functional layer 400 may be formed on the wiring structure 200 so that the display device 1 of FIG. 1 may be manufactured. Specifically, the light-emitting element connecting pattern 2320 of the wiring structure 200 and the pixel electrode 3100 of the light-emitting element layer 300 may contact each other. After the wiring structure 200 and the light-emitting element layer 300 are connected to each other, the upper functional layer 400 may be formed on the light-emitting element layer 300.

FIG. 17 is a view illustrating a conventional display device for explaining the effect of the display device of FIG. 1.

Referring to FIGS. 3 and 17, a conventional display device for implementing high resolution may include a semiconductor element layer 500. The conventional semiconductor element layer 500 may correspond to the semiconductor element layer 100 of FIG. 3.

The conventional semiconductor element layer 500 includes a silicon wafer substrate 510, a first gate insulating film 532, a second gate insulating film 534, a silicide film 540, a first spacer 542, a second spacer 544, a third spacer 546, a fourth spacer 548, a first gate electrode 552, a second gate electrode 554, an element isolation film 560, a via insulating layer 580, a first connecting pattern 582, a second connecting pattern 584, a third connecting pattern 586, and a fourth connecting pattern 588. The silicon wafer substrate 510 includes a first well 512, a second well 514, a first drain 522, a first source 524, a second drain 526, and a second source 528.

A driving transistor T-TR1’ of the conventional semiconductor element layer 500 is defined by the first well 514, the first drain 522, the first source 524, the first gate electrode 552, the first connecting pattern 582, and the second connecting pattern 584. A switching transistor T-TR2’ of the conventional semiconductor element layer 500 is defined by the second well 514, the second drain 526, the second source 528, the second gate electrode 554, the third connecting pattern 586, and the fourth connecting pattern 588.

To form the conventional semiconductor element layer 500, first, the entire silicon wafer substrate 510 is doped with a p-type dopant, and then the first well 512 and the second well 514 are doped with an n-type dopant. Thereafter, a gate insulating layer made of silicon oxide is formed on the silicon wafer substrate 510 and patterned to form the first gate insulating film 532 and the second gate insulating film 534. Next, the element isolation film 560 is formed, and the first gate electrode 552 and the second gate electrode 554 are formed. Then, the first drain 522, the first source 524, the second drain 526, and the second source 528 are doped with a p-type dopant. Thereafter, a silicide film 540 is formed to lower the contact resistance of the first connecting pattern 582, the second connecting pattern 584, the third connecting pattern 586, and the fourth connecting pattern 588 which contact the first drain 522, the first source 524, the second drain 526, and the second source 528, and the first spacer 542 and the second spacer 544 are formed on the side surface of the first gate electrode 552, and the third spacer 546 and the fourth spacer 548 are formed on the side surface of the second gate electrode 554. Thereafter, a via insulating layer 580 is formed, and the first connecting pattern 582, the second connecting pattern 584, the third connecting pattern 586, and the fourth connecting pattern 588 are formed to penetrate the via insulating layer 580 in a thickness direction.

Compared to a manufacturing method of the conventional semiconductor element layer 500 described with reference to FIGS. 4, 5, 6, 7, 8, 9, 10, 11, 12, 13, 14, 15, and 16, a manufacturing method of the semiconductor element layer 100 included in the display device 1 may require fewer doping steps, may omit forming the silicide film 540, and may omit forming spacers (e.g., like 542, 544, 546, and 548) on the respective side surfaces of the gate electrodes. Accordingly, the manufacturing process of the semiconductor element layer 100 is simplified compared to the manufacturing method of the conventional semiconductor element layer 500, thereby reducing manufacturing time and cost of the semiconductor element layer 100. As a result, while reducing the manufacturing time and cost of the display device 1, structures for high-resolution implementation may be easily formed on the base substrate 1100 including a silicon wafer through a FEOL process and a BEOL process, thereby enabling easy manufacture of the display device 1 with improved display quality and also providing the display device 1 with enhanced display quality.

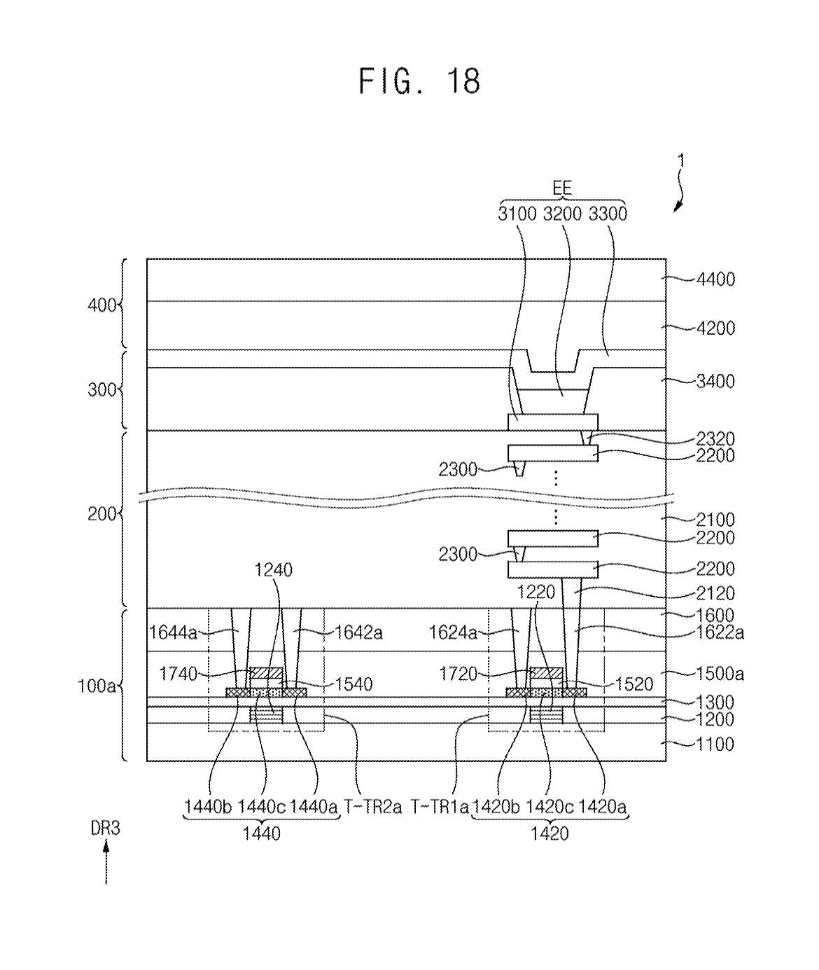

FIG. 18 is a cross-sectional view illustrating another example of a portion of a cross section of the display device of FIG. 1.

Referring to FIG. 18, a structure of the display device 1 described with reference to FIG. 18 may be substantially a same as or similar to the structure of the display device 1 described with reference to FIG. 3, except for the structure differing due to additionally including a first upper gate insulating layer 1520, a second upper gate insulating layer 1540, a first upper gate electrode 1720, and a second upper gate electrode 1740.

Hereinafter, descriptions overlapping with those explained with reference to FIG. 3 may be omitted or briefly explained.

Referring to FIG. 18, the display device 1 may include a semiconductor element layer 100a. The semiconductor element layer 100a may include the first upper gate insulating layer 1520, the second upper gate insulating layer 1540, the first upper gate electrode 1720, the second upper gate electrode 1740, a first connecting pattern 1622a, a second connecting pattern 1624a, a third connecting pattern 1642a, and a fourth connecting pattern 1644a.

The first gate electrode 1220, the first active pattern 1420, the first upper gate electrode 1720, the first connecting pattern 1622a, and the second connecting pattern 1624a may collectively define a first type transistor T-TR1a. The second gate electrode 1240, the second active pattern 1440, the second upper gate electrode 1740, the third connecting pattern 1642a, and the fourth connecting pattern 1644a may collectively define a second type transistor T-TR2a.

In the disclosure, the first upper gate electrode 1720 and the second upper gate electrode 1740 may be referred to as second gate electrodes. In addition, the first upper gate insulating layer 1520 and the second upper gate insulating layer 1540 may be referred to as second gate insulating layers.

The first upper gate insulating layer 1520 may be arranged on the first active pattern 1420. In an embodiment, the first upper gate insulating layer 1520 may overlap the first channel area 1420c in a plan view. In addition, the first upper gate insulating layer 1520 may not overlap the first drain region 1420a and the first source region 1420b in a plan view.

The second upper gate insulating layer 1540 may be arranged on the second active pattern 1440. In an embodiment, the second upper gate insulating layer 1540 may overlap the second channel area 1440c in a plan view. Also, the second upper gate insulating layer 1540 may not overlap the second drain region 1440a and the second source region 1440b in a plan view.

However, the first upper gate insulating layer 1520 and the second upper gate insulating layer 1540 according to embodiments of the present disclosure may not be limited thereto, and the first upper gate insulating layer 1520 and the second upper gate insulating layer 1540 may be connected to each other in a cross-sectional view to define a single layer and may cover the first drain region 1420a, the first source region 1420b, the second drain region 1440a, and the second source region 1440b as a whole.

The first upper gate electrode 1720 may be arranged on the first upper gate insulating layer 1520. In an embodiment, the first upper gate electrode 1720 may overlap the first channel area 1420c in a plan view. The first upper gate electrode 1720 may be the upper gate electrode of the first type transistor T-TR1a. Also, the first gate electrode 1220 may be the lower gate electrode of the first type transistor T-TR1a. In an embodiment, the first upper gate electrode 1720 may include a conductive material.

The second upper gate electrode 1740 may be arranged on the second upper gate insulating layer 1540. In an embodiment, the second upper gate electrode 1740 may overlap the second channel area 1440c in a plan view. The second upper gate electrode 1740 may be the upper gate electrode of the second type transistor T-TR2a. Also, the second gate electrode 1240 may be the lower gate electrode of the second type transistor T-TR2a. In an embodiment, the second upper gate electrode 1740 may include a conductive material.

In an embodiment, the second insulating layer 1500a may cover the first upper gate electrode 1720 and the second upper gate electrode 1740 on the gate insulating layer 1300. Accordingly, the thickness of the second insulating layer 1500a of FIG. 18 may be greater than the thickness of the second insulating layer 1500 of FIG. 3.

The first connecting pattern 1622a may fill a contact hole penetrating the second insulating layer 1500a and the planarization layer 1600 in a thickness direction. The first connecting pattern 1622a may perform substantially a same role or function as the first connecting pattern 1622 of FIG. 3.

The second connecting pattern 1624a may fill a contact hole penetrating the second insulating layer 1500a and the planarization layer 1600 in a thickness direction. The second connecting pattern 1624a may perform substantially a same role or function as the second connecting pattern 1624 of FIG. 3.

The third connecting pattern 1642a may fill a contact hole penetrating the second insulating layer 1500a and the planarization layer 1600 in a thickness direction. The third connecting pattern 1642a may perform substantially a same role or function as the third connecting pattern 1642 of FIG. 3.

The fourth connecting pattern 1644a may fill a contact hole penetrating the second insulating layer 1500a and the planarization layer 1600 in a thickness direction. The fourth connecting pattern 1644a may perform substantially a same role or function as the fourth connecting pattern 1644 of FIG. 3.

Except for having a dual gate structure, the first type transistor T-TR1a may be substantially the same as the first type transistor T-TR1 of FIG. 3. Except for having a dual gate structure, the second type transistor T-TR2a may be substantially a same as the second type transistor T-TR2 of FIG. 3.

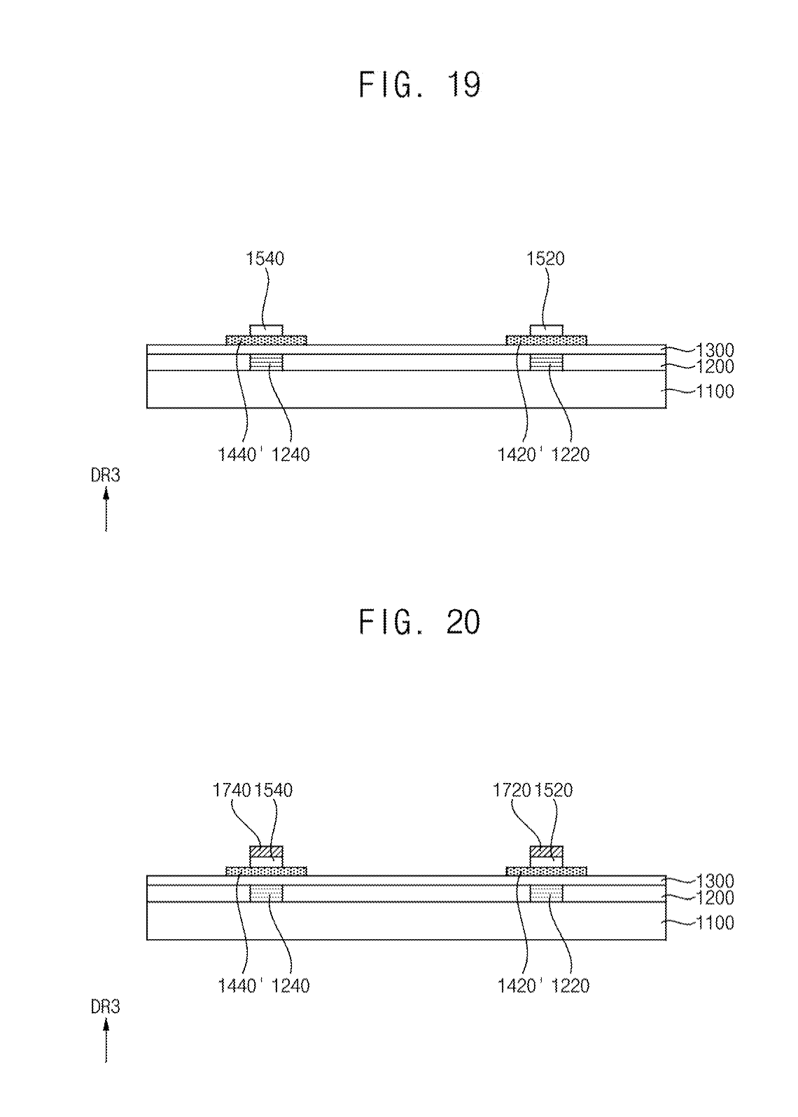

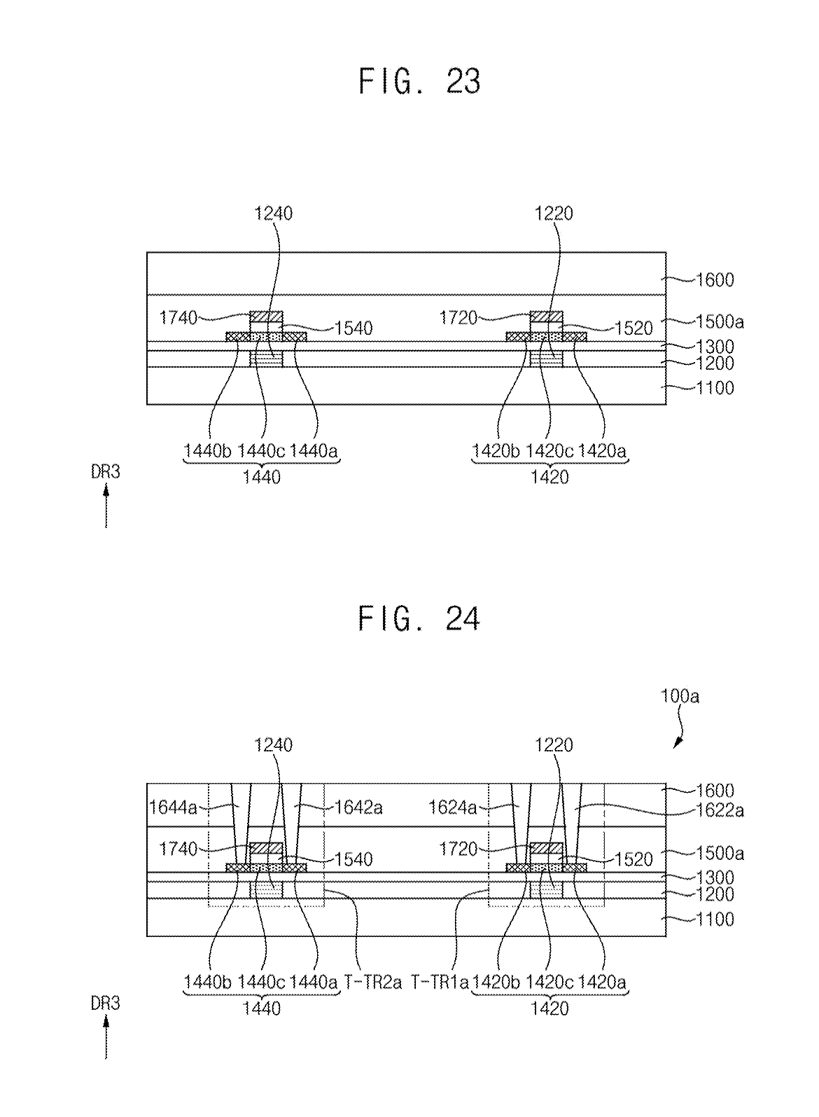

FIGS. 19, 20, 21, 22, 23, and 24 are views illustrating a method for manufacturing the display device of FIG. 18.

A method of manufacturing the display device described with reference to FIGS. 19, 20, 21, 22, 23, and 24 may be substantially a same as or similar to the method of manufacturing the display device 1 described with reference to FIGS. 4, 5, 6, 7, 8, 9, 10, 11, 12, 13, 14, 15, and 16, except for a doping process and a process of forming the first upper gate insulating layer 1520, the second upper gate insulating layer 1540, the first upper gate electrode 1720, and the second upper gate electrode 1740.

In addition, the method of manufacturing the display device described with reference to FIGS. 19, 20, 21, 22, 23, and 24 may correspond to the processes performed after manufacturing processes of FIGS. 4, 5, 6, 7, 8, 9, and 10.

Hereinafter, overlapping descriptions with those described with reference to FIGS. 4, 5, 6, 7, 8, 9, 10, 11, 12, 13, 14, 15, and 16 and FIG. 18 may be omitted or briefly described.

Referring to FIG. 19, the first insulating layer 1200, the first gate electrode 1220, and the second gate electrode 1240 may be formed on the base substrate 1100. The gate insulating layer 1300 may be formed on the first insulating layer 1200, the first gate electrode 1220, and the second gate electrode 1240. A patterned first preliminary active pattern 1420’ and a second preliminary active pattern 1440’ may be formed on the gate insulating layer 1300.

After the first preliminary active pattern 1420’ and the second preliminary active pattern 1440’ are formed, a first upper gate insulating layer 1520 may be formed on the first preliminary active pattern 1420’. In addition, a second upper gate insulating layer 1540 may be formed on the second preliminary active pattern 1440’. For example, a preliminary upper gate insulating layer covering the first preliminary active pattern 1420’ and the second preliminary active pattern 1440’ may be formed on the gate insulating layer 1300, and the first upper gate insulating layer 1520 and the second upper gate insulating layer 1540 may be formed by removing portions of the preliminary upper gate insulating layer.

Specifically, a portion of the preliminary upper gate insulating layer overlapping the first gate electrode 1220 in a plan view may remain to form the first upper gate insulating layer 1520. Also, a portion of the preliminary upper gate insulating layer overlapping the second gate electrode 1240 in a plan view may remain to form the second upper gate insulating layer 1540.

Referring to FIG. 20, the first upper gate electrode 1720 may be formed on the first upper gate insulating layer 1520. The second upper gate electrode 1740 may be formed on the second upper gate insulating layer 1540. The first upper gate electrode 1720 may overlap the first gate electrode 1220 in a plan view. The second upper gate electrode 1740 may overlap the second gate electrode 1240 in a plan view.

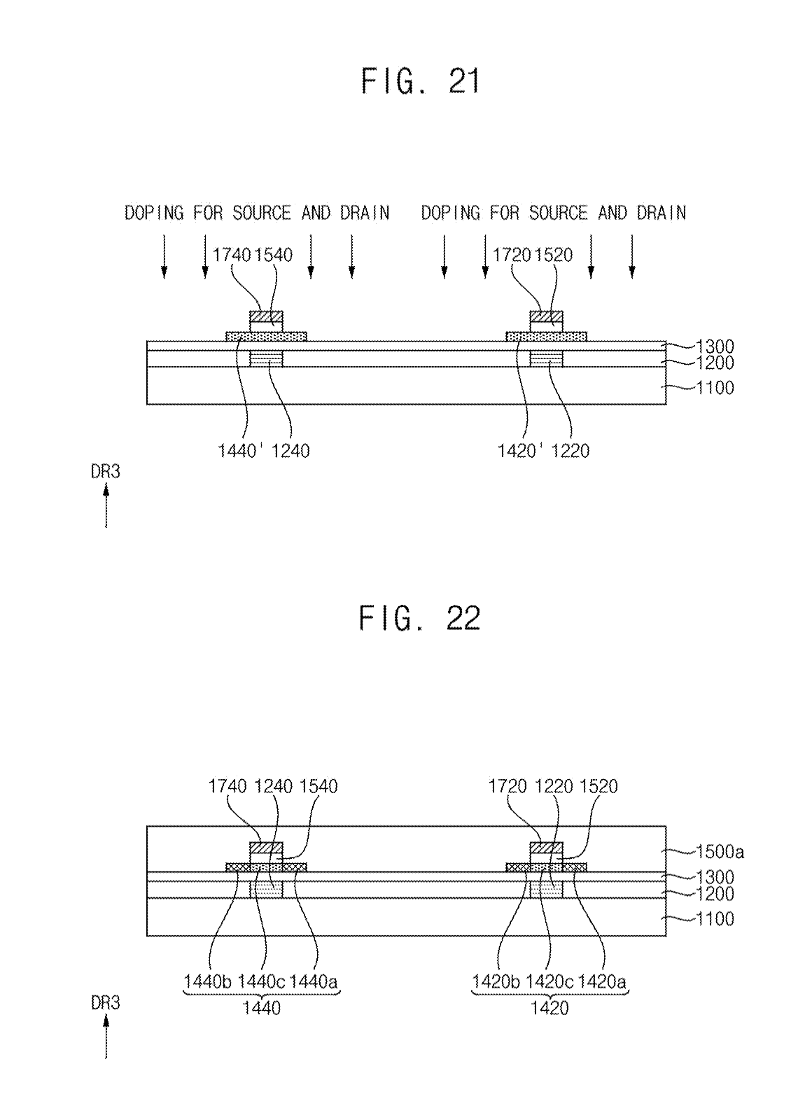

Referring to FIGS. 21 and 22, doping may be performed on the first preliminary active pattern 1420’ using the first upper gate electrode 1720 as a mask. For example, doping may be performed on a portion of the first preliminary active pattern 1420’ that does not overlap the first upper gate electrode 1720 in a plan view to form a doped portion in the first preliminary active pattern 1420’. Accordingly, the doped portion of the first preliminary active pattern 1420’ may be formed as the first drain region 1420a and the first source region 1420b. Therefore, the first active pattern 1420 including the first drain region 1420a, the first source region 1420b, and a first channel area 1420c may be formed.

Doping may be performed on the second preliminary active pattern 1440’ using the second upper gate electrode 1740 as a mask. For example, doping may be performed on a portion of the second preliminary active pattern 1440’ that does not overlap the second upper gate electrode 1740 in a plan view to form a doped portion in the second preliminary active pattern 1440’. Accordingly, the doped portion of the second preliminary active pattern 1440’ may be formed as a second drain region 1440a and a second source region 1440b. Therefore, a second active pattern 1440 including the second drain region 1440a, the second source region 1440b, and a second channel area 1440c may be formed. In the disclosure, doping of the first and second preliminary active patterns 1420’ and 1440’ for forming the first source 1420b, the second source 1440b, the first drain 1420a, and the second drain 1440a may be referred to as a second doping process.

Referring to FIGS. 22, 23, and 24, the second insulating layer 1500a may be formed on the gate insulating layer 1300. For example, the second insulating layer 1500a may be formed on the gate insulating layer 1300 to cover the first gate electrode 1720 and the second gate electrode 1740. After the second insulating layer 1500a is formed, a planarization layer 1600 may be formed. After the planarization layer 1600 is formed, a contact hole penetrating the second insulating layer 1500a and the planarization layer 1600 in a thickness direction may be formed.

After the contact holes are formed, the first connecting pattern 1622a, the second connecting pattern 1624a, the third connecting pattern 1642a, and a fourth connecting pattern 1644a filling the contact holes may be formed. After the first connecting pattern 1622a, the second connecting pattern 1624a, the third connecting pattern 1642a, and the fourth connecting pattern 1644a are formed and the semiconductor element layer 100a is manufactured, the wiring structure 200, the light-emitting element layer 300, and the upper functional layer 400 of FIG. 18 may be sequentially formed along the third direction DR3, and accordingly, the display device 1 of FIG. 1 may be manufactured.

Referring further to FIG. 17, the manufacturing method of the semiconductor element layer 100a included in the display device 1 described with reference to FIGS. 4, 5, 6, 7, 8, 9, 10, 11, 12, 13, 14, 15, and 16 may have fewer doping steps, may omit forming a separate silicide film 540, and may omit forming spacers (e.g., like 542, 544, 546, and 548) on the sides of the gate electrodes, compared to the manufacturing method of the conventional semiconductor element layer 500. Accordingly, the manufacturing process of the semiconductor element layer 100 may be simplified compared to the manufacturing process of the conventional semiconductor element layer 500, and the manufacturing time and cost of the semiconductor element layer 100a may be reduced. Therefore, while reducing the manufacturing time and cost of the display device 1, structures for high-resolution implementation may be easily formed on the base substrate 1100 including a silicon wafer through FEOL and BEOL processes, thereby enabling easy manufacture of a display device 1 with improved display quality.

In addition, since the driving transistor and the switching transistor (e.g., the first, second, third, and fourth transistors T1, T2, T3, T4 of FIG. 2) included in the semiconductor element layer 100a have a dual gate structure, a display device 1 capable of more stable operation may be implemented.

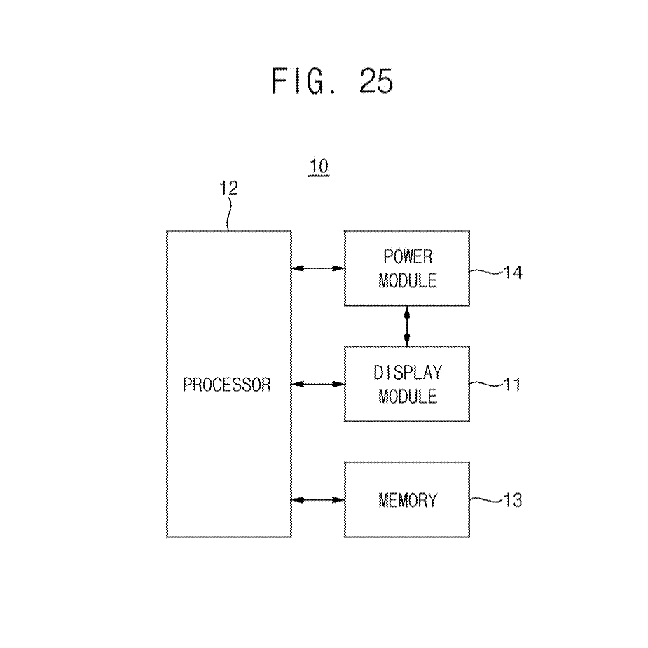

The display device (e.g., the display device 1 of FIG. 1) according to an embodiment may be applied to various electronic devices. An electronic device (e.g., the electronic device 10 of FIG. 25) according to an embodiment may include the above-described display device and may further include modules or devices having additional functions other than the display device

FIG. 25 is a block diagram of an electronic device according to an embodiment.

Referring to FIG. 25, an electronic device 10 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

The memory 13 may store data and information required for the operation of the processor 12 or the display module 11. When the processor 12 executes an application stored in the memory 13, an image data signal and/or an input control signal may be transmitted to the display module 11. The display module 11 may process the received signal and output image information through a display screen.

The power module 14 may include a power supply module such as a power adapter or a battery device, and a power conversion module that converts the power supplied by the power supply module to generate power necessary for the operation of the electronic device 10.

At least one of the components of the electronic device 10 described above may be included in the display device according to the above-described embodiments. In addition, among the individual modules included in a functionally integrated module, some may be included in the display device (e.g., the display device 1 of FIG. 1), while others may be provided separately from the display device. For example, the display device may include the display module 11, and the processor 12, memory 13, and power module 14 may be provided in the electronic device 10 in the form of separate devices, not as part of the display device.

In an embodiment, the display device included in the electronic device 10 may be manufactured according to the method illustrated in FIGS. 4, 5, 6, 7, 8, 9, 10, 11, 12, 13, 14, 15, and 16 or the method illustrated in FIGS. 19, 20, 21, 22, 23, and 24. In an embodiment, the display device may be driven by receiving the image data signal and/or the input control signal from the processor 12. Accordingly, since the electronic device 10 includes the display device, the electronic device 10 may be easily manufactured with reduced manufacturing cost and time.

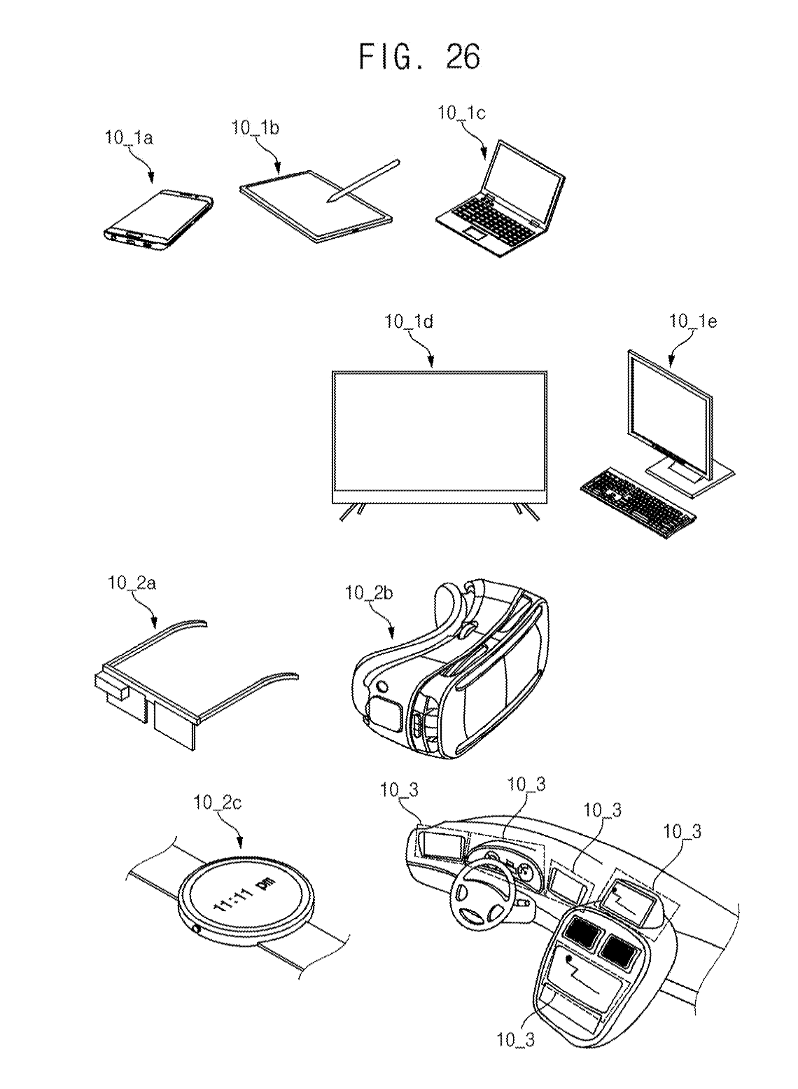

FIG. 26 is schematic views of electronic devices according to various embodiments.

Referring to FIG. 26, various electronic devices (e.g., the electronic device 10 of FIG. 25) to which the display device (e.g., the display device 1 of FIG. 1) according to embodiments is applied may include not only image display electronic devices such as a smartphone 10_1a, a tablet PC 10_1b, a laptop 10_1c, a TV 10_1d, and a desktop monitor 10_1e, but also wearable electronic devices including a display module such as smart glasses 10_2a, a head-mounted display 10_2b, and a smartwatch 10_2c, and vehicle electronic devices 10_3 including a display module, such as a cluster, a center fascia, a dashboard-mounted CID (center information display), and a room mirror display.

The method and the device according to the embodiments may be applied to a display device included in a computer, a notebook, a mobile phone, a smartphone, a smart pad, a portable multimedia player (PMP), a personal digital assistant (PDA), an MP3 player, or the like.

Although the methods and the devices according to the embodiments have been described with reference to the drawings, the illustrated embodiments are examples, and may be modified and changed by a person having ordinary knowledge in the relevant technical field without departing from the technical spirit described in the following claims.

What is claimed is:

1. A display device comprising:
a base substrate;
a first insulating layer on the base substrate and defining a gate hole which exposes an upper surface of the base substrate;
a first gate electrode on the base substrate, filling the gate hole, and having a thickness equal to a thickness of the first insulating layer;
an active pattern on the first gate electrode, the active pattern overlapping the first gate electrode in a plan view;
a planarization layer on the active pattern, the planarization layer comprising a contact hole that exposes a portion of the active pattern;
a connecting pattern filling the contact hole on the active pattern and contacting the portion of the active pattern which is exposed;
a wiring structure on the planarization layer, the wiring structure comprising a semiconductor-element-connecting pattern connected to the connecting pattern and a plurality of wiring layers sequentially stacked; and
a light-emitting element electrically connected to the active pattern through the wiring structure and configured to emit light.

2. The display device of claim 1, further comprising:
a first gate insulating layer between the first gate electrode and the active pattern in a cross-sectional view; and
a second insulating layer on the first gate insulating layer and the active pattern.

3. The display device of claim 2, wherein a thickness of the active pattern is equal to a thickness of the first gate insulating layer.

4. The display device of claim 2, wherein the connecting pattern penetrates the second insulating layer and the planarization layer in a thickness direction.

5. The display device of claim 2, further comprising:
a second gate insulating layer on the active pattern; and
a second gate electrode on the second gate insulating layer, the second gate electrode overlapping the active pattern in a plan view.

6. The display device of claim 5, wherein the first gate electrode, the second gate electrode, the active pattern, and the connecting pattern define a transistor,
wherein the first gate electrode is a lower gate electrode of the transistor, and
wherein the second gate electrode is an upper gate electrode of the transistor.

7. The display device of claim 1, wherein the base substrate comprises a silicon wafer.

8. The display device of claim 6, wherein the first insulating layer comprises silicon oxycarbide (SiOC).

9. A method of manufacturing a display device, a method comprising:
forming a first insulating layer having a gate hole on a base substrate;
forming a first gate electrode on the base substrate, filling the gate hole and having a thickness equal to a thickness of the first insulating layer;
forming an active pattern on the first insulating layer of which a portion overlaps the first gate electrode in a plan view;
forming a connecting pattern on the active pattern, the connecting pattern contacting a portion of the active pattern;
forming a wiring structure comprising an insulating structure and a plurality of wiring layers sequentially stacked in the insulating structure; and
electrically connecting the connecting pattern to the wiring structure.

10. The method of claim 9, wherein the forming of the first gate electrode includes:
forming the gate hole exposing an upper surface of the base substrate by removing a portion of the first insulating layer in a thickness direction;
applying a metal material filling the gate hole; and
performing a planarization process in which an upper surface of the metal material and an upper surface of the first insulating layer have an equal level based on the base substrate.

11. The method of claim 9, wherein the forming of the active pattern includes:
forming a first gate insulating layer on the first gate electrode and the first insulating layer;
forming a preliminary active layer covering the first gate insulating layer entirely on the first gate insulating layer;
performing a first doping process on the preliminary active layer to form a channel; and
forming a preliminary active pattern by patterning the preliminary active layer which is doped.

12. The method of claim 11, wherein the forming of the active pattern further includes:
forming a second insulating layer on the preliminary active pattern;
forming a mask pattern on the second insulating layer, the mask pattern overlapping a portion of the preliminary active pattern and the first gate electrode in a plan view; and
performing a second doping process on the preliminary active pattern to form a source and a drain.

13. The method of claim 11, wherein the forming of the active pattern further includes:
forming a second gate insulating layer on the preliminary active pattern;
forming a second gate electrode on the second gate insulating layer, the second gate electrode overlapping a portion of the preliminary active pattern and the first gate electrode in a plan view; and
performing a second doping process on the preliminary active pattern using the second gate electrode as a mask to form a source and a drain.

14. The method of claim 9, wherein the forming of the connecting pattern includes:
forming a planarization layer on the active pattern;
form a contact hole which exposes a portion of the active pattern by removing a portion of the planarization layer in a thickness direction; and
filling the contact hole with the connecting pattern.

15. The method of claim 9, wherein the first gate electrode, the active pattern, and the connecting pattern forms a transistor,
wherein the base substrate, the first insulating layer, and the transistor are included in a semiconductor element layer, and
wherein the semiconductor element layer is formed through a front end of line (FEOL) process.

16. The method of claim 9, wherein the forming of the wiring structure is performed through a back end of line (BEOL) process.

17. The method of claim 9, wherein the wiring structure comprises:
a semiconductor-element-connecting pattern at a bottom of the wiring structure; and
a light-emitting element connecting pattern at a top of the wiring structure,
wherein in the connecting of the connecting pattern and the wiring structure, the connecting pattern contacts the semiconductor-element-connecting pattern.

18. The method of claim 17, further comprising:
forming a light-emitting element layer comprising a pixel electrode, a light-emitting layer, and a common electrode sequentially stacked on the wiring structure, the light-emitting layer configured to emit light; and
connecting the wiring structure and the light-emitting element layer,
wherein in the connecting of the wiring structure and the light-emitting element layer, the light-emitting element connecting pattern contacts the pixel electrode.

19. An electronic device comprising:
a processor configured to output an image data signal and an input control signal; and
a display device configured to driven based on the image data signal and the input control signal,
wherein the display device comprises:
a base substrate;
a first insulating layer on the base substrate, the first insulation layer comprising a gate hole which exposes an upper surface of the base substrate;
a first gate electrode on the base substrate, the first gate electrode filling the gate hole and having a thickness equal to a thickness of the first insulating layer;
an active pattern on the first gate electrode, the active pattern overlapping the first gate electrode in a plan view;
a planarization layer on the active pattern, the planarization layer comprising a contact hole that exposes a portion of the active pattern;
a connecting pattern filling the contact hole on the active pattern and contacting the portion of the active pattern which is exposed;
a wiring structure on the planarization layer and comprising a semiconductor-element-connecting pattern connected to the connecting pattern and a plurality of wiring layers sequentially stacked; and
a light-emitting element connected to the active pattern through the wiring structure and configured to emit light.

20. The electronic device of claim 19, wherein the base substrate, the first insulating layer, the first gate electrode, the active pattern, the planarization layer, and the connecting pattern are formed through a front end of line (FEOL) process, and
wherein the wiring structure is formed through a back end of line (BEOL) process.
